(19) United States
(12) Patent Application Publication
(10) Pub. No.: US 2025/0014978 A1
(43) Pub. Date: Jan. 9, 2025

(54) PACKAGE MODULE INCLUDING AN INTERPOSER WITH A DUMMY VIA, PACKAGE STRUCTURE INCLUDING THE PACKAGE MODULE AND METHODS OF FORMING THE SAME

(71) Applicant: Taiwan Semiconductor Manufacturing Company Limited, Hsinchu (TW)

(72) Inventors: Chin-Hua Wang, New Taipei City (TW); Chun-Wei Chen, Taoyuan City (TW); Tsung-Yen Lee, Hemei Township (TW); Shin-Puu Jeng, Po-Shan Village (TW)

(21) Appl. No.: 18/346,457

(22) Filed: Jul. 3, 2023

(51) Int. Cl. H01L 23/498; H01L 21/56; H01L 23/00; H01L 23/31; H01L 23/48; H01L 25/065

(52) U.S. Cl. CPC H01L 23/49822; H01L 21/565; H01L 23/3128; H01L 23/481; H01L 24/16; H01L 24/32; H01L 24/73; H01L 25/0657; H01L 2224/16225; H01L 2224/32225; H01L 2224/73204; H01L 2225/06541; H01L 2924/181

(57) ABSTRACT

A package module includes an interposer including a dummy via formation region having a dummy via, a plurality of semiconductor dies on the interposer, wherein an edge of a semiconductor die in the plurality of semiconductor dies is over the dummy via formation region, and a molding material layer on the interposer encapsulating the plurality of semiconductor dies. A method of making a package module includes forming an interposer including a dummy via formation region having a dummy via, attaching a plurality of semiconductor dies to the interposer, wherein an edge of a semiconductor die in the plurality of semiconductor dies is over the dummy via formation region, and forming a molding material layer on the interposer to encapsulate the plurality of semiconductor dies.

### BACKGROUND

A probing test is a test that involves making electrical contact with specific nodes on a semiconductor device using a probe needle. This type of testing is typically performed to verify that the semiconductor device meets the desired performance specifications before it is packaged and shipped to customers.

In the probing test, a probe needle is positioned over a specific contact pad on the semiconductor device. The needle is then lowered and pressed against the contact pad, establishing an electrical connection between the probe needle and the contact pad. This process is repeated for all the contact pads on the device for which testing is desired. Once the probe needle is in contact with the contact pads, various electrical tests may be performed to verify that the semiconductor device meets the desired specifications. These tests may include measuring the resistance, capacitance, or other electrical parameters at the various test nodes. The results of the electrical tests may be analyzed to determine whether the semiconductor device meets the desired specifications.

During these probing tests, the semiconductor device may be deformed in a manner that may induce interposer crack. Such deformations may also occur during operation of the semiconductor device due to thermal expansion and differences among the coefficients of thermal expansion (CTE) of the different materials used to form the semiconductor device. In many instances, the top-die and substrate of a semiconductor device may induce increased tensile stress on the interposer at the top-die/molding edge as the molding may have a lower rigidity to support the interposer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a package module according to one or more embodiments.

FIG. 1B is a plan view (e.g., top-down view) of the package module according to one or more embodiments.

FIG. 1C is a detailed vertical cross-sectional view of a portion of the package module, and a corresponding plan view of the portion, according to one or more embodiments.

FIG. 1D is a plan view (e.g., top-down view) of the interposer in the package module according to one or more embodiments.

FIG. 2A is a vertical cross-sectional view of an intermediate structure including the semiconductor material layer according to one or more embodiments.

FIG. 2B is a vertical cross-sectional view of an intermediate structure including the TSVs and the dummy vias in the semiconductor material layer, according to one or more embodiments.

FIG. 2C is a vertical cross-sectional view of an intermediate structure including the bonding layer and upper bonding pads according to one or more embodiments.

FIG. 2D is a vertical cross-sectional view of an intermediate structure including the first semiconductor die and second semiconductor die according to one or more embodiments.

FIG. 2E is a vertical cross-sectional view of an intermediate structure including the molding material layer according to one or more embodiments.

FIG. 2F is a vertical cross-sectional view of an intermediate structure after the thinning of the semiconductor material layer, according to one or more embodiments.

FIG. 2G is a vertical cross-sectional view of an intermediate structure including the plurality of C4 bumps, according to one or more embodiments.

FIG. 3 is a flow chart illustrating a method of forming a package module according to one or more embodiments.

FIG. 4A is a vertical cross-sectional view of the package structure including the package module, according to one or more embodiments.

FIG. 4B is a plan view (e.g., top-down view) of the package structure including the package module, according to one or more embodiments.

FIG. 5A is a vertical cross-sectional view of an intermediate structure including the package substrate having package substrate upper bonding pads and package substrate lower bonding pads, according to one or more embodiments.

FIG. 5B is a vertical cross-sectional view of an intermediate structure in which the package module may be attached to the package substrate, according to one or more embodiments.

FIG. 5C is a vertical cross-sectional view of an intermediate structure in which the package underfill layer may be formed on the package substrate, according to one or more embodiments.

FIG. 5D is a vertical cross-sectional view of an intermediate structure in which the adhesive layer may be applied to the package substrate according to one or more embodiments.

FIG. 5E is a vertical cross-sectional view of an intermediate structure in which the stiffener ring may be attached to (e.g., mounted on) the package substrate according to one or more embodiments.

FIG. 5F is a vertical cross-sectional view of an intermediate structure in which a plurality of solder balls may be formed on the package substrate according to one or more embodiments.

FIG. 6 is a flow chart illustrating a method of forming a package module according to one or more embodiments.

FIG. 7A is a detailed vertical cross-sectional view of a first alternative design of the interposer according to one or more embodiments.

FIG. 7B is a detailed vertical cross-sectional view of a second alternative design of the interposer according to one or more embodiments.

FIG. 8A is a detailed vertical cross-sectional view of a first alternative design pattern of the dummy vias according to one or more embodiments.

FIG. 8B is a detailed vertical cross-sectional view of a second alternative design pattern of the dummy vias according to one or more embodiments.

FIG. 8C is a detailed vertical cross-sectional view of a third alternative design pattern of the dummy vias according to one or more embodiments.

FIG. 8D is a detailed vertical cross-sectional view of a fourth alternative design pattern of the dummy vias according to one or more embodiments.

FIG. 9 is a plan view (e.g., top-down view) of a fourth alternative design pattern of the dummy vias according to one or more embodiments.

FIG. 10 is a vertical cross-sectional view of an alternative design of the package module according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

After a probing test (e.g., e-test), a package module including one more semiconductor dies on an interposer may experience various stresses that may lead to an interposer crack (e.g., a crack in the interposer). There may be several causes of interposer cracks during the probing test. First, the probing test may involve applying mechanical pressure to the interposer using a probe needle. In instances in which the force applied is too high, the interposer may experience overloading, leading to cracks. Second, the interposer and the semiconductor die may have different coefficients of thermal expansion (CTE). During a probing test, the interposer may heat up due to the applied electrical current, leading to differential thermal expansion between the interposer and the die. This can result in cracks in the interposer. Third, the interposer may contain material defects such as voids, inclusions, or weak spots. In instances in which the package module may be subjected to the mechanical stress of the probing test, these material defects may cause the interposer to crack. Fourth, the interposer's design may not adequately account for the stresses that occur during the probing test. For example, the interposer may be too thin or lack the necessary reinforcements to withstand the probing test's mechanical stress.

The interposer crack may occur, for example, at an edge of a top die in the package module. The interposer crack may be caused by a flattening of the package module which may have a somewhat curved shape due to warpage. That is, during the probing test, the package module may be flattened to be substantially flat causing the interposer crack to occur. The top die and package substrate may induce worse tensile stress on the interposer at an edge of the top die and molding material (e.g., top die/molding edge) while the molding material may have a lower rigidity to support the interposer.

At least one embodiment of the present disclosure may include a reinforced interposer. The interposer may be included, for example, in a package module including a system of integrated chips. In particular, the interposer may include a dummy via pattern in the interposer to enhance a structure of the package module and mitigate against the risk of an interposer crack.

In at least one embodiment, one or more dummy vias may be placed in a specified area of the interposer. The specified area of the interposer may be nearby an edge of one or more of the top dies in the package module. The dielectric layers of the interposer may have a combined thickness T. A thickness T_{V} of the dummy vias may be given as 1 μm<T_{V}<T.

An overlap distance D between the edge of the top die and an edge of the specified area may be given such that D≤2 mm. The top die may have a width W and a length L. Thus, the specified area for placement of the dummy vias may be represented by the formula 2D*(L+W)*2 or [4D*(L+W)]. An area of an individual dummy via may be given as C. The total area of the dummy via pattern on the specified area may be given as ΣC. Thus, an area ratio or ratio of total area of the dummy via pattern on the specified area to the specified area for placement of the dummy vias (ΣC/[4D*(L+W)]) may be in a range from about 0.1 to about 0.99.

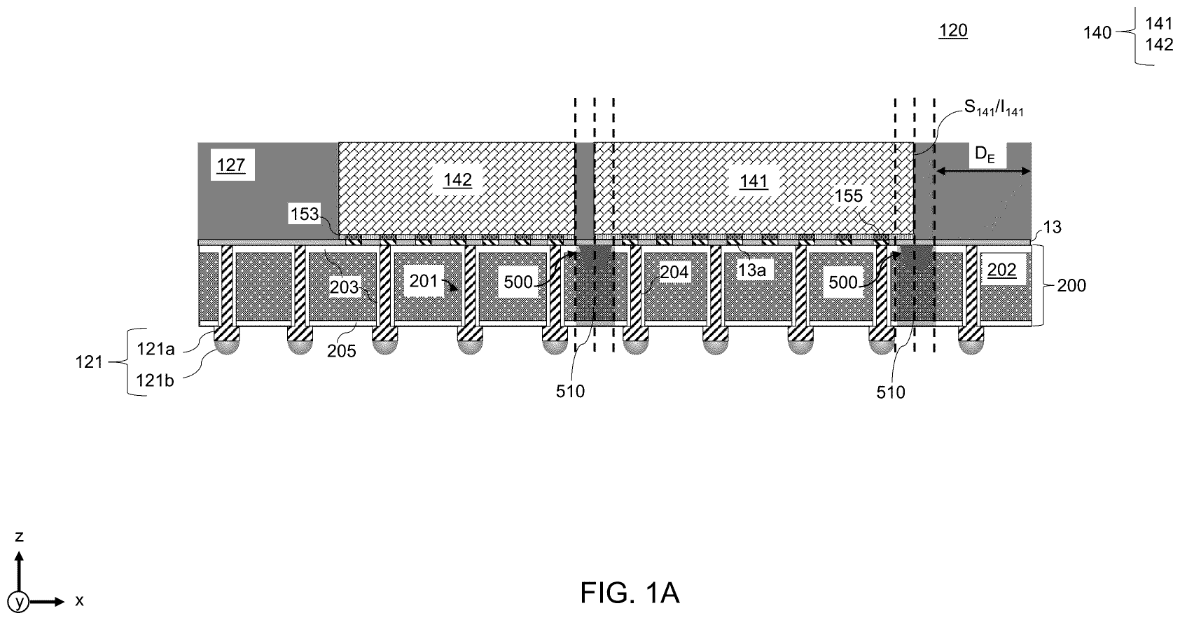

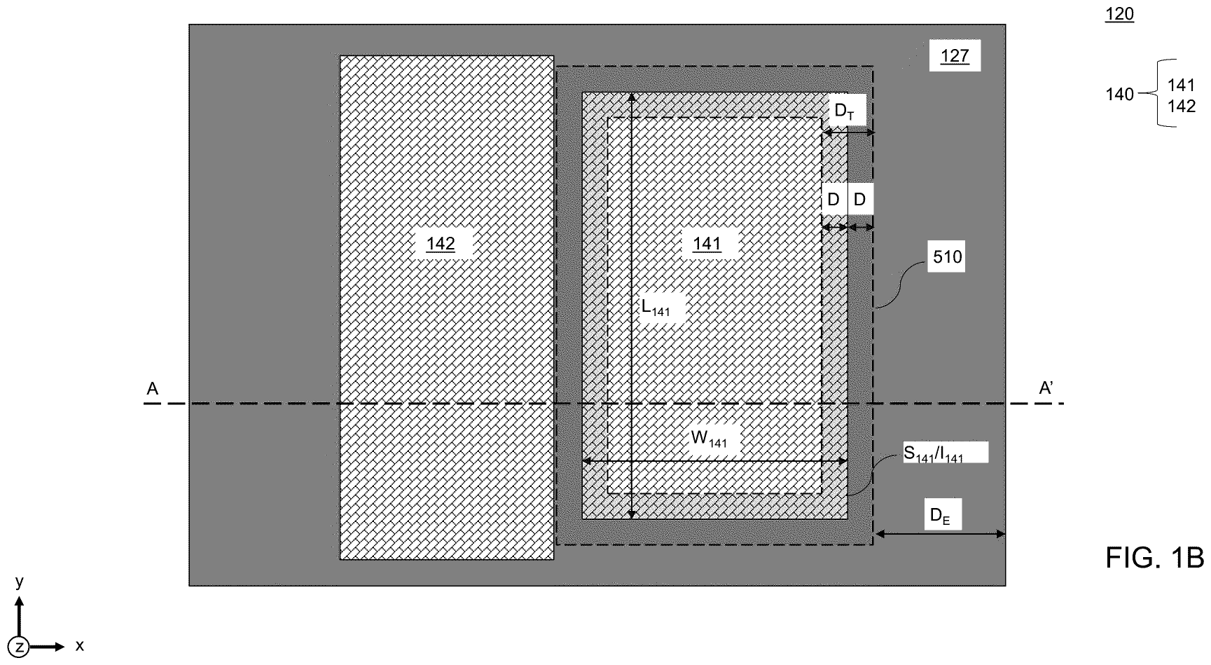

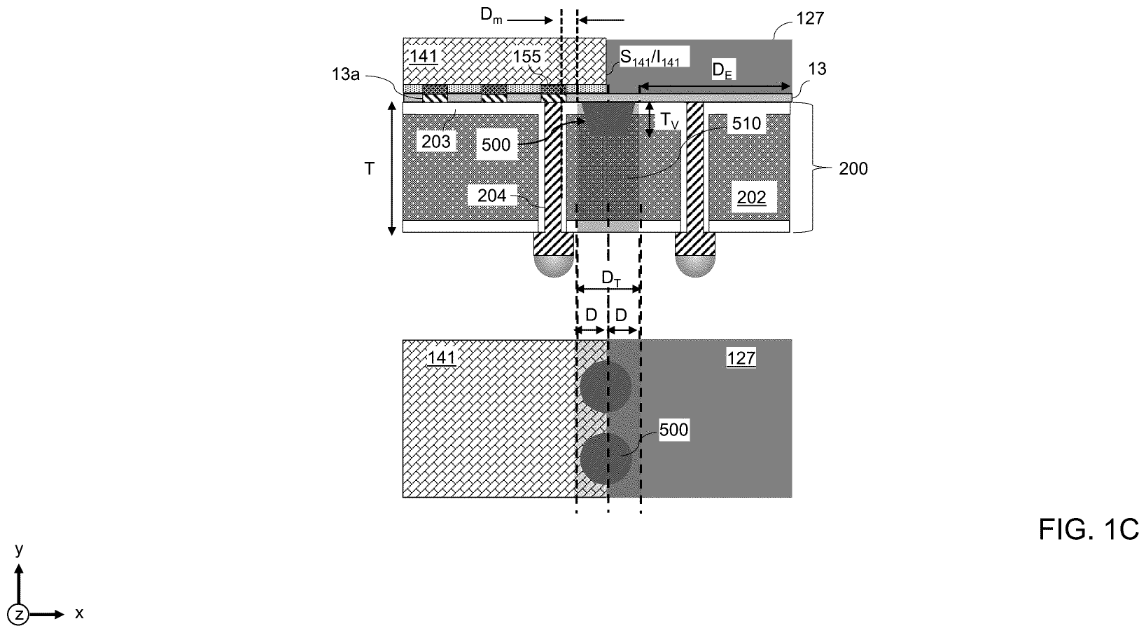

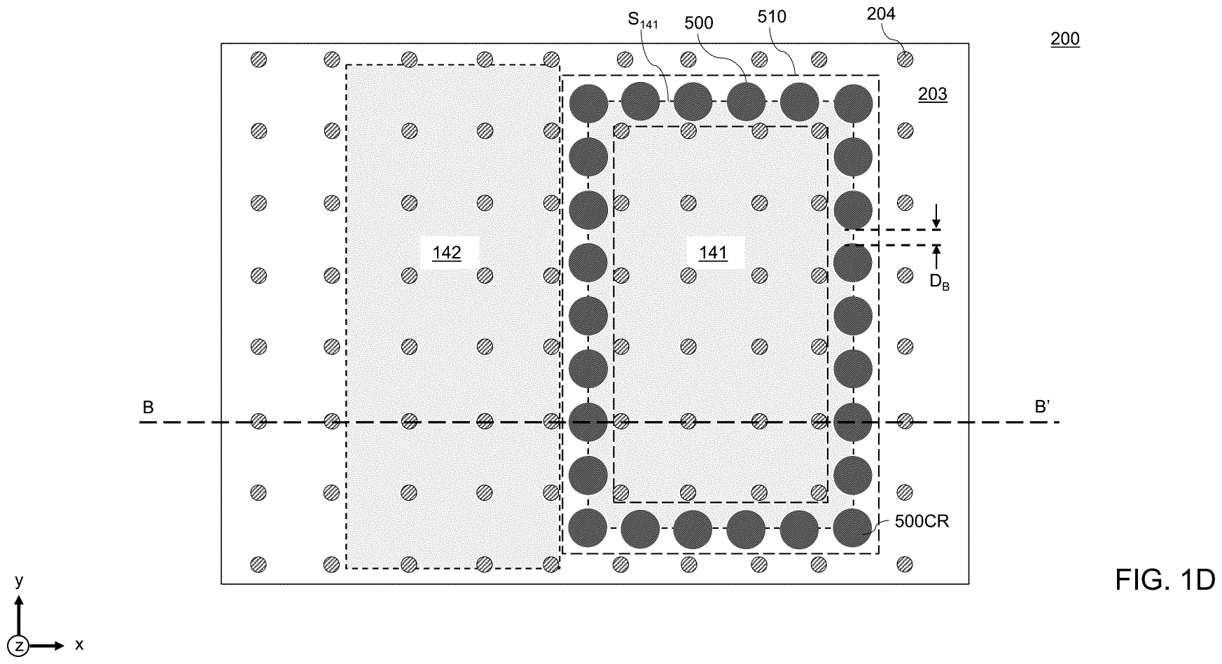

FIG. 1A is a vertical cross-sectional view of a package module 120 according to one or more embodiments. FIG. 1B is a plan view (e.g., top-down view) of the package module 120 according to one or more embodiments. The vertical cross-sectional view in FIG. 1A is along the line A-A′ in FIG. 1B. FIG. 1C is a detailed vertical cross-sectional view of a portion of the package module 120, and a corresponding plan view of the portion, according to one or more embodiments. FIG. 1D is a plan view (e.g., top-down view) of the interposer 200 in the package module 120 according to one or more embodiments. The line B-B′ in FIG. 1D corresponds to the line A-A′ in FIG. 1B (i.e., the vertical cross-sectional view of the interposer 200 in FIG. 1A is along the line B-B′ in FIG. 1D).

As illustrated in FIG. 1A, the package module 120 may include a first semiconductor die 141 and second semiconductor die 142 (e.g., semiconductor chips). Although the package module 120 is illustrated in FIG. 1A as including two semiconductor dies 141, 142 having a particular arrangement, the number of semiconductor dies and the arrangement of the semiconductor dies is not limited to the number and arrangement in FIG. 1A. In particular, the first semiconductor die 141 and second semiconductor die 142 may constitute a semiconductor die set, and the package module 120 may include a plurality of the semiconductor die sets. The first semiconductor die 141 and second semiconductor die 142 may be referred to collectively as the semiconductor dies 140.

The package module 120 may further include an interposer 200, which may include an inorganic interposer. The interposer 200 may include a semiconductor material layer 202. In at least one embodiment, the semiconductor material layer 202 may include a silicon-based semiconductor material. The semiconductor material layer 202 may include single crystalline silicon or polycrystalline silicon. The semiconductor material layer 202 may be undoped or doped with electrical dopants such as p-type dopants or n-type dopants.

The interposer 200 may include a plurality of via cavities 201 in the semiconductor material layer 202. The via cavities 201 may extend in the z-direction through an entirety of the semiconductor material layer 202. A lateral dimension (such as the diameter) of the via cavities 201 may be in a range from 0.5 micron to 10 microns, such as from 1 micron to 6 microns, although lesser and greater lateral dimensions may also be used. In one embodiment, the pattern of the array of via cavities 201 may have a two-dimensional periodicity over the interposer 200.

An insulating liner 203 may be formed in peripheral portions of the via cavities 201 and on an upper surface of the semiconductor material layer 202. The insulating liner 203 may include, for example, silicon oxide, silicon nitride, low-k dielectric materials such as carbon-doped oxides, extremely low-k dielectric materials such as porous carbon doped silicon dioxide, a combination thereof or other suitable material. The insulating liner 203 may have a thickness in a range from 1% to 20%, such as from 2% to 5% of the lateral dimension of the via cavities 201.

A plurality of through silicon vias (TSVs) 204 may be located in the plurality of via cavities 201, respectively. The TSVs 204 may include at least one conductive material, such as at least one metallic material, in a central portion of the via cavities 201. The TSVs 204 and the front insulating liner 203 may substantially fill the via cavities 201. The TSVs 204 may include, for example, a combination of a metallic barrier material (such as TiN, TaN, WN, MON, TiC, TaC, WC, etc.) and a metallic fill material (such as Cu, Co, Ru, Mo, W, etc.). Other suitable metallic barrier materials and metallic fill materials are within the contemplated scope of disclosure.

The interposer 200 may also include a lower insulating layer 205 on a bottom surface of the semiconductor material layer 202. The lower insulating layer 205 may adjoin the insulating liner 203 in the via cavities 201. The lower insulating layer 205 may include a material that is the same or similar to the material of the insulating liner 203. The lower insulating layer 205 may include, for example, silicon oxide, silicon nitride, low-k dielectric materials such as carbon-doped oxides, extremely low-k dielectric materials such as porous carbon doped silicon dioxide, a combination thereof or other suitable material.

As illustrated in FIG. 1A, a plurality of C4 bumps 121 may connected to the TSVs 204 on the board-side surface of the interposer 200, respectively. The C4 bumps 121 may be located at least partially on the lower insulating layer 205. The lower insulating layer 205 may serve to electrically insulate the C4 bumps 121 from the semiconductor material layer 202. The C4 bumps 121 may include a contact pad 121a (e.g., copper/nickel contact pad) on the TSVs 204 (e.g., in contact with the TSVs 204), respectively. The C4 bumps 121 may also include a solder bump 121b (e.g., SnAg solder bump) on the contact pad 121a. The package module 120 may be connected to a substrate such as a package substrate through the C4 bumps 121.

As illustrated in FIG. 1A, the package module 120 may further include a bonding layer 13 on an upper surface (e.g., chip-side surface) of the interposer 200. The bonding layer 13 may include a dielectric layer such as silicon oxide, low-k dielectric materials such as carbon-doped oxides, extremely low-k dielectric materials such as porous carbon doped silicon dioxide, a combination thereof or other suitable materials.

One or more upper bonding pads 13a may be formed in the bonding layer 13 on the upper surface of the interposer 200, as illustrated in FIG. 1C. The bonding layer 13 may at least partially cover the upper bonding pads 13a. The upper bonding pads 13a may be connected (e.g., electrically coupled) to the TSVs 204 in the interposer 200. The upper bonding pads 13a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure. In at least one embodiment, a material of the upper bonding pads 13a may be the same as a material of the TSVs 204 in the interposer 200.

The first semiconductor die 141 and second semiconductor die 142 may be attached to (e.g., mounted on) the upper surface of the interposer 200 through the bonding layer 13 and the upper bonding pads 13a. In particular, the first semiconductor die 141 and second semiconductor die 142 may be attached (e.g., flip-chip mounted) on the upper surface of the interposer 200. That is, an active region of the semiconductor dies 140 may face the interposer 200 and a bulk semiconductor region of the semiconductor dies 140 may be opposite the active region. The upper surfaces of the semiconductor dies 140 (e.g., upper surface of the bulk semiconductor region) may be substantially coplanar. In particular, the upper surfaces of the semiconductor dies 140 may be located at a same height measured from an upper surface of the bonding layer 13.

The semiconductor dies 140 may include a die bonding layer 153 on the active region side of the semiconductor dies 140. The die bonding layer 153 may include a material substantially the same as the material in the bonding layer 13. The die bonding layer 153 may include a dielectric material such as silicon oxide, low-k dielectric materials such as carbon-doped oxides, extremely low-k dielectric materials such as porous carbon doped silicon dioxide, a combination thereof or other suitable material. The semiconductor dies 140 may also include one or more die bonding pads 155 in the die bonding layer 153. The die bonding pads 155 may be at least partially exposed through the die bonding layer 153. The die bonding pads 155 may have a size (e.g., area) in the x-y plane that is substantially the same as a size of the upper bonding pads 13a in the bonding layer 13.

The semiconductor dies 140 may be bonded to the interposer 200 by a hybrid bond which may also be known as direct bonding or wafer-to-wafer bonding. The hybrid bond may include a metallic portion and a dielectric portion. In at least one embodiment, the hybrid bond may include a metal-metal bond and an oxide-oxide bond. In particular, the hybrid bond may include a bond between the die bonding pads 155 and the upper bonding pads 13a, and a bond between the die bonding layer 153 and the bonding layer 13 (e.g., oxide layer) on the interposer 200. The hybrid bond may enable high-density interconnects and efficient signal transfer between the semiconductor dies 140 and the interposer 200.

Each of the semiconductor dies 140 may include, for example, a semiconductor die, a system on chip die, or a system on integrated chips die, and may be implemented by chip on wafer on substrate technology or integrated fan-out on substrate technology. In particular, each of the semiconductor dies 140 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., high-bandwidth memory (HBM) die, hybrid memory cube (HMC), dynamic random access memory (DRAM) die, a Wide I/O die, a M-RAM die, a R-RAM die, a NAND die, static random access memory (SRAM), etc.), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, a IPD die (e.g., integrated passives device), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc.

In at least one embodiment, the first semiconductor die 141 may include a primary die and the second semiconductor die 142 may include an ancillary die. In at least one embodiment, the first semiconductor die 141 may include an SOC die and the second semiconductor die 142 may include a memory die (e.g., memory/SOC die, HBM die, etc.).

The package module 120 may also include a molding material layer 127 over the interposer 200 (e.g., on the bonding layer 13) on and around the semiconductor dies 140 and between the semiconductor dies 140. The molding material layer 127 may be formed on (e.g., cover) and bonded to one or more sidewalls (e.g., all of the sidewalls) of the semiconductor dies 140. In at least one embodiment, the semiconductor dies 140 may be substantially encapsulated or “embedded” within the molding material layer 127. The molding material layer 127 may also be formed on and bonded to a surface of the bonding layer 13.

In at least one embodiment, the molding material layer 127 may contact a sidewall S₁₄₁ of the first semiconductor die 141 so that at least a portion of the sidewall S₁₄₁ of the first semiconductor die 141 may constitute a die/molding material interface I₁₄₁. The die/molding material interface I₁₄₁ may be formed, for example, around an entire periphery of the first semiconductor die 141. The die/molding material interface I₁₄₁ may be formed laterally around one or more of the sidewalls S₁₄₁ of the first semiconductor die 141. That is, the die/molding material interface I₁₄₁ may wrap around an entirety of the first semiconductor die 141 in the x and y directions. The sidewalls S₁₄₁ and die/molding material interface I₁₄₁ may also extend in the z-direction across an entirety of the first semiconductor die 141. In at least one embodiment, the sidewalls S₁₄₁ and die/molding material interface I₁₄₁ may extend in the z-direction from a bottom of the die bonding layer 153 (which may contact the bonding layer 13 on the interposer 200) to an upper surface of the semiconductor die 141.

An upper surface of the molding material layer 127 may be substantially uniform (e.g., flat). The upper surface may also be substantially coplanar with the upper surface of the semiconductor dies 140. An outer sidewall of the molding material layer 127 may be substantially aligned with an outer sidewall of the bonding layer 13 and an outer sidewall of the interposer 200. In at least one embodiment, an outer sidewall of the package module 120 may be constituted at least in part by the outer sidewall of the molding material layer 127, at least in part by the outer sidewall of the bonding layer 13 and at least in part by the outer sidewall of the interposer 200.

In at least one embodiment, the molding material layer 127 may be formed of a curable material that may cure to form a hard, solid structure. The molding material layer 127 may include, for example, epoxy molding compound (EMC). In at least one embodiment, the molding material layer 127 may include a polymeric material and in particular, an epoxy-based polymeric material. Other suitable molding materials may be used.

In at least one embodiment, the molding material layer 127 may have a CTE that is substantially similar to a CTE of the interposer 200. In at least one embodiment, the molding material layer 127 may include an added material (e.g., filler material) for improving a property of the molding material layer 127 (e.g., thermal conductivity, CTE, etc.). The added material may include, for example, metal powder, metal oxide powder, etc. Other materials in the molding material layer 127 are within the contemplated scope of the disclosure.

As further illustrated in FIG. 1A, the interposer 200 may include one or more dummy vias 500. The dummy via 500 may be located in a dummy via formation region 510 (indicated by a shaded area in FIG. 1A) in the interposer 200. The dummy via formation region 510 may be located in the semiconductor material layer 202 of the interposer 200. The dummy via formation region 510 may extend in a z-direction, for example, from a bottom surface of the lower insulating layer 205 to an upper surface of the insulating liner 203. In at least one embodiment, a distance DE between the dummy via formation region 510 and the outer sidewall of the package module 120 (e.g., outer sidewall of the molding material layer 127) may be in a range from 0.5 mm to 5 mm.

As illustrated in FIG. 1A, the dummy via 500 (e.g., filler via, non-functional via, etc.) may be located in an uppermost portion of the semiconductor material layer 202 and at an upper surface of the interposer 200. In particular, an upper surface of the dummy via 500 may substantially coplanar with an upper surface of the insulating liner 203 between the bonding layer 13 and the semiconductor material layer 202. The dummy via 500 may be made of one or more layers of rigid materials such as metals, metal alloys, etc. Other materials are within the contemplated scope of disclosure. The dummy via 500 may be located near a sidewall S₁₄₁ of the first semiconductor die 141. In at least one embodiment, at least a portion of the dummy via 500 may be located under the sidewall S₁₄₁ of the first semiconductor die 141. In at least one embodiment, the dummy via 500 may be located under the sidewall S₁₄₁ and the die/molding material interface I₁₄₁.

The dummy vias 500 may reinforce the interposer 200. The dummy vias 500 may help to inhibit formation of an interposer crack, for example, at the edge of the semiconductor die 141. In particular, the dummy vias 500 may inhibit the formation of the interposer crack caused by a probing test during which the package module 120 may be substantially flattened. In at least one embodiment, the dummy vias 500 may inhibit the formation of the interposer crack at the die/molding material interface I₁₄₁.

The dummy vias 500 may also help to improve the overall performance and reliability of the package module 120. The dummy vias 500 may be strategically placed, for example, between the TSVs 204 (e.g., functional vias) to match a pitch across the interposer 200 (e.g., across the entire interposer 200). This may help reduce the pitch variation and maintain a more consistent interconnect density, improving manufacturing yield and signal integrity. The dummy vias 500 may also be configured as spacing elements that may increase a distance between adjacent TSVs 204. Such spacing may help to reduce crosstalk (e.g., unwanted coupling of signals between adjacent interconnects). As a result, the signal quality may be enhanced and noise may be reduced. The dummy vias 500 may also help to balance a thermal expansion mismatch between different components. In particular, by distributing a coefficient of thermal expansion (CTE) difference more evenly, the mechanical stress on the interposer 200 may be reduced, minimizing the risk of warpage and other reliability issues.

As illustrated in FIG. 1B, the upper surfaces of the semiconductor dies 140 may be exposed through the molding material layer 127. The second semiconductor die 142 may be located on a side (in the x-direction) of the first semiconductor die 141. The first semiconductor die 141 may have a width W₁₄₁ in the x-direction that is greater than a width of the second semiconductor die 142 in the x-direction. The first semiconductor die 141 may have a length L₁₄₁ in the y-direction that is less than a length of the second semiconductor die 142 in the y-direction.

For ease of understanding, a location of the dummy via formation region 510 in the underlying interposer 200 is indicated in FIG. 1B by shading and outlined by dashed lines. As illustrated in FIG. 1B, the dummy via formation region 510 may have a frame shape in the plan view. The first semiconductor die 141 may overlap the dummy via formation region 510 by an overlap distance D. The overlap distance D may be less than or equal to 2 mm. A total distance DT between an inner edge and outer edge of the dummy via formation region 510 may be given as 2D. A total distance DT between an inner edge and outer edge of the dummy via formation region 510 may be less than or equal to 4 mm.

A center of the dummy die formation region 510 may be substantially aligned with the sidewall S₁₄₁ and with the die/molding material interface I₁₄₁. In at least one embodiment, a center of the dummy die formation region 510 may be substantially aligned with the sidewall S₁₄₁ and with the die/molding material interface I₁₄₁ around an entire periphery of the first semiconductor die 141. In at least one embodiment, the total distance Dr of the dummy via formation region 510 may be substantially uniform around the entire periphery of the first semiconductor die 141. In at least one embodiment, the dummy via formation region 510 may have a substantially box-shape without a top and bottom, and with a wall thickness of DT.

In the plan view, an area of the dummy via formation region 510 may be given as (2×2D(L₁₄₁))+(2×2D(W₁₄₁))=4D×(L₁₄₁+W₁₄₁). In addition, an area of an individual dummy via 500 (not shown in FIG. 1B) is given as C, the total area of the dummy vias 500 (e.g., a dummy via pattern) in the dummy via formation region 510 in the area may be given as ΣC. Thus, the ratio of the total area of the dummy vias 500 to the dummy via formation region 510 (also referred to as the area ratio) may be represented by the equation ΣC/[4D×(L₁₄₁+W₁₄₁)]. The area ratio may be in a range from about 0.1 to about 0.99. Thus, the total area of the dummy vias 500 may occupy 10% of the area of the dummy formation region 510 to about 99% of the dummy via formation region 510.

Referring to FIG. 1C, an upper portion of FIG. 1C is the detailed vertical cross-sectional view of the package module 120 and a lower portion of FIG. 1C is the plan view of the package module 120. As illustrated in the top portion of FIG. 1C, the dummy via 500 may have a substantially trapezoidal vertical cross-sectional shape. The horizontal cross-sectional shape may be circular, oval, hexagon, or any polygon shape. Other vertical and horizontal cross-sectional shapes of the dummy via 500 are within the contemplated scope of disclosure. The dummy via 500 may have a thickness T_{V} and extend from the upper surface of the insulating liner 203 into the semiconductor material layer 202. The dummy via 500 may be separated (e.g., electrically isolated) from the TSVs 204 by the insulating liner 203 and the semiconductor material layer 202. In particular, a minimum distance Dₘ (e.g., minimum lateral distance) between the dummy vias 500 and the TSVs 204 may be at least 50 microns. While the minimum distance Dₘ in FIG. 1C is illustrated to the left of the dummy via 500, one of ordinary skill in the art may understand that the minimum distance Dₘ may occur to the right of the dummy via 500 and corresponding adjacent TSVs 204. The dummy via 500 may also be separated (e.g., electrically isolated) from other conductive structures (e.g., metallic structures) in the interposer 200 and from the upper bonding pads 13a in the bonding layer 13. Further, the interposer 200 may have a total thickness T that includes a thickness of the insulating liner 203, a thickness of the semiconductor material layer 202 and a thickness of the lower insulating layer 205. A thickness T_{V} of the dummy via 500 may be greater than 1 μm and less than or equal to the total thickness T of the interposer 200 (e.g., 1 μm<T_{V}≤T).

As illustrated in the bottom portion of FIG. 1C, the dummy via 500 may have a substantially circular shape in the plan view. Other plan view shapes of the dummy via 500 are within the contemplated scope of disclosure. A center of the dummy via 500 may be substantially aligned with a center of the dummy via formation region 510. A largest diameter of the dummy via 500 (e.g., a diameter of the upper surface of the dummy via 500) may be less than the total distance DT between an inner edge and outer edge of the dummy via formation region 510.

Referring again to FIG. 1D, an outline of the first semiconductor die 141 and the second semiconductor die 142 are illustrated in this plan view of the interposer 200 for ease of understanding. As illustrated in FIG. 1D, a plurality of the dummy vias 500 may be formed under the sidewalls S₁₄₁ of the first semiconductor die 141. A center of the dummy vias 500 may be substantially aligned with the sidewalls S141/die/molding material interface I₁₄₁ around the entire periphery of the first semiconductor die 141. Thus, in at least one embodiment, where the first semiconductor die 141 has a rectangular shape, the dummy vias 500 may be arranged to have a substantially similar rectangular shape. A spacing DB between the dummy vias 500 may be less than the diameter of the dummy vias 500. The spacing DB between the dummy vias 500 may vary or be substantially uniform around the periphery of the first semiconductor die 141. The dummy vias 500 may include a corner dummy via 500CR that is formed under a corner of the first semiconductor die 141. While the dummy vias 500 in FIG. 1D have substantially the same shape and size, it is possible for the dummy vias 500 to have different shapes and sizes.

As further illustrated in FIG. 1D, at the upper surface of the interposer 200, the dummy vias 500 may be separated from the TSVs 204 by the insulating liner 203. In at least one embodiment, the TSVs 204 may have a pitch (e.g., in the x-direction and/or the y-direction) that is greater than the spacing DB between the dummy vias 500.

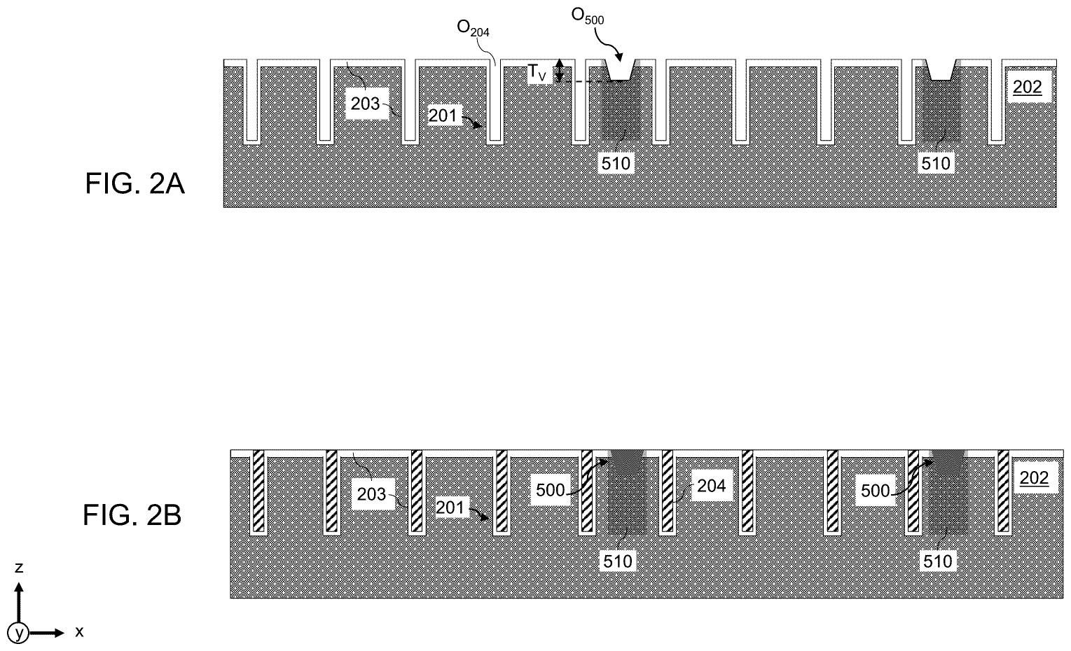

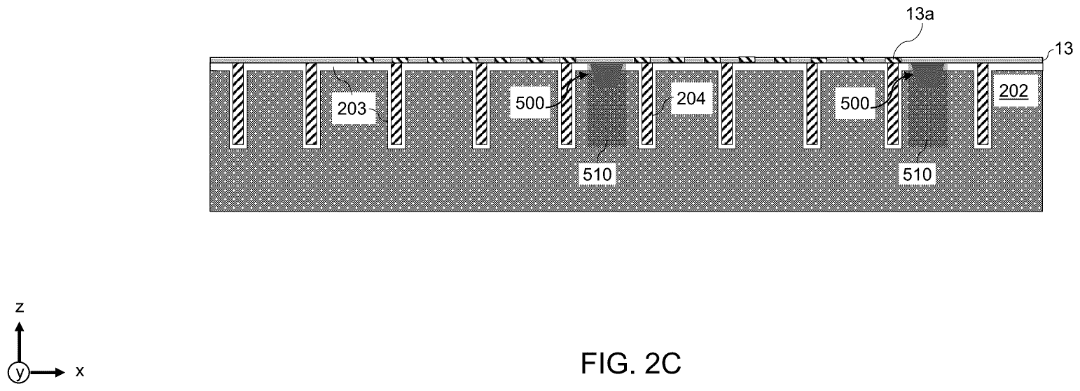

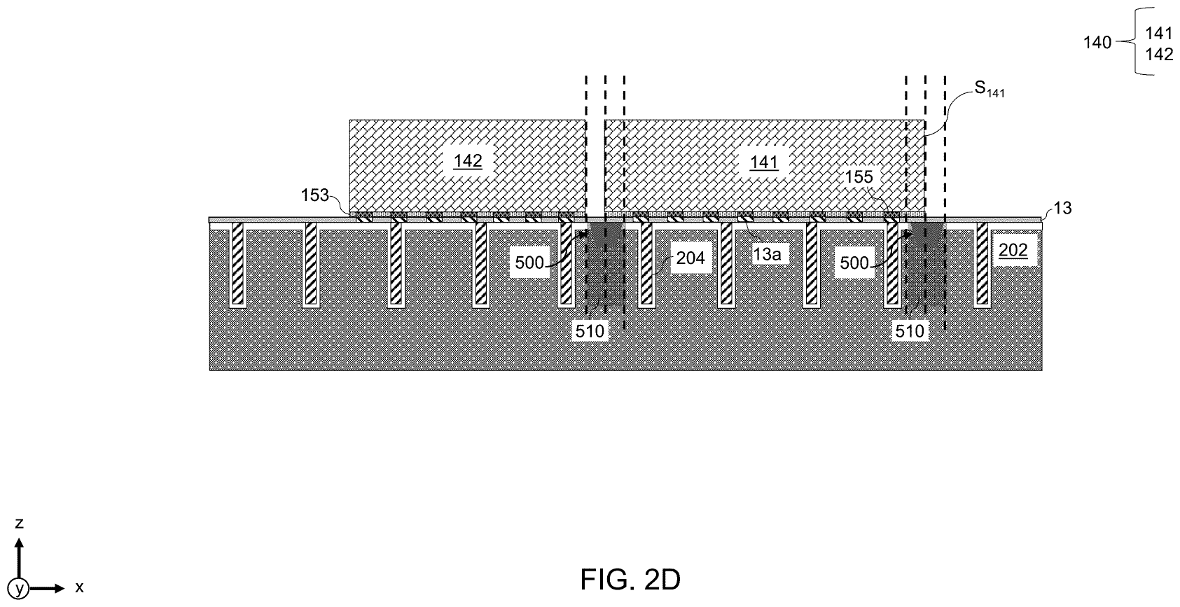

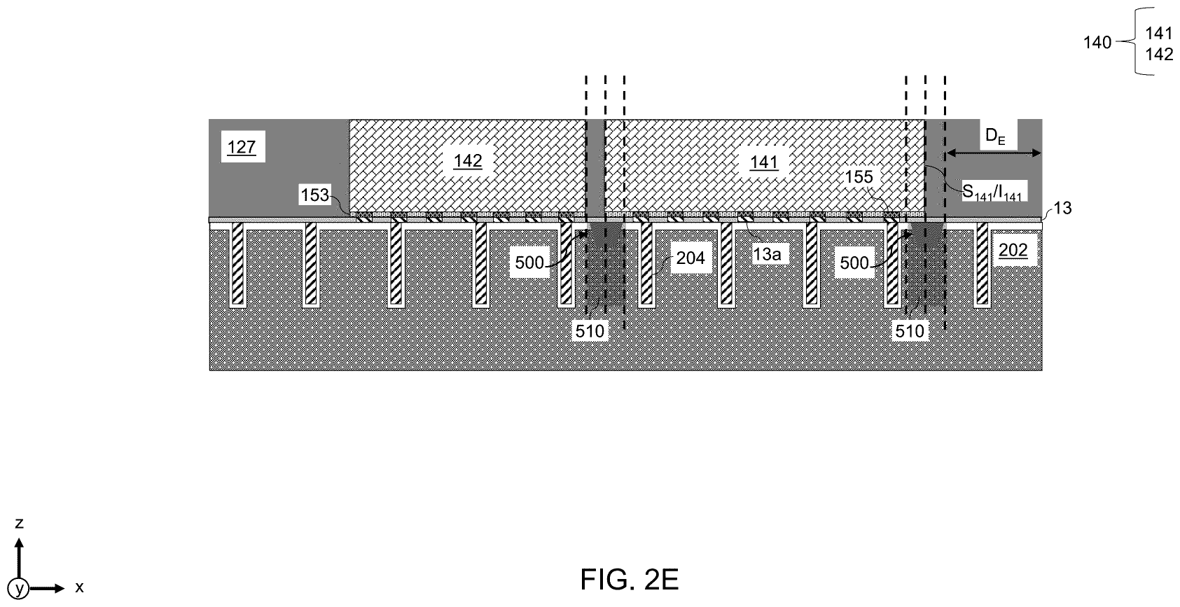

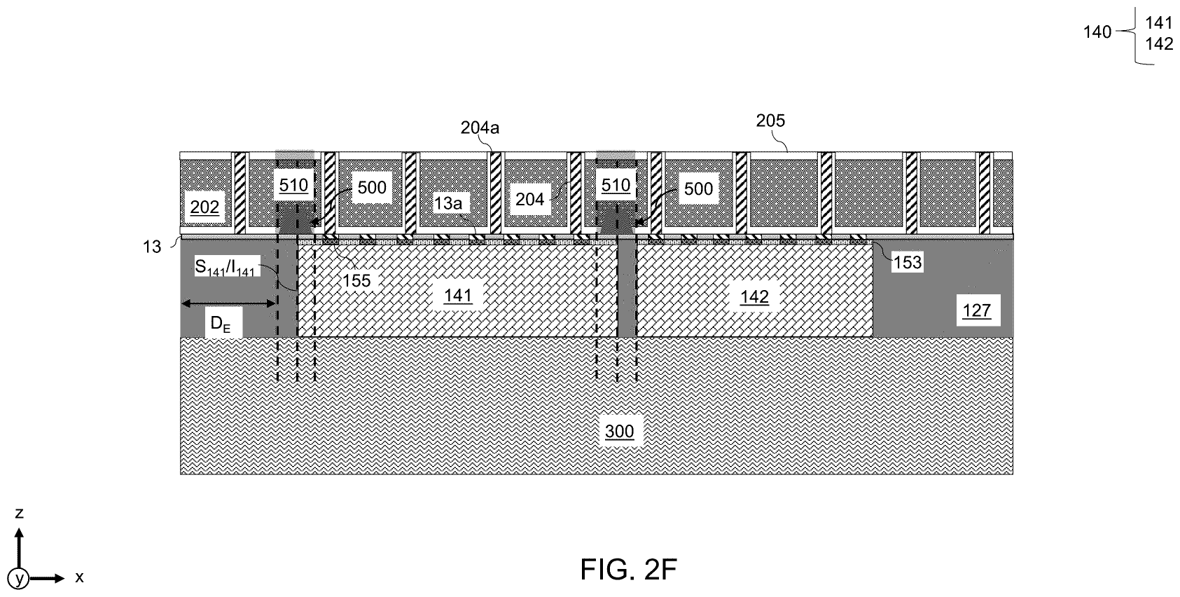

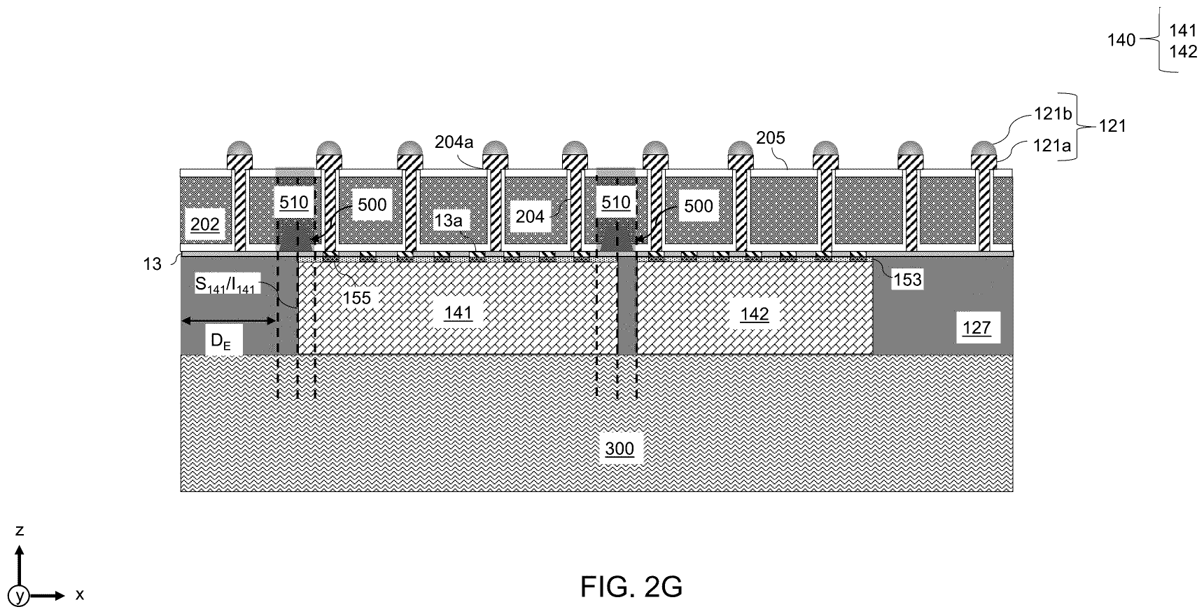

FIGS. 2A-2E illustrate various intermediate structures that may be formed during various stages in a method of forming the package module 120 according to one or more embodiments. FIG. 2A is a vertical cross-sectional view of an intermediate structure including the semiconductor material layer 202 of the interposer 200 according to one or more embodiments.

In the intermediate structure of FIG. 2A, the semiconductor material layer 202 may include, for example, a silicon wafer. The via cavities 201 may be formed in an upper portion of the silicon wafer. In one embodiment, the silicon wafer may be a commercially available silicon wafer having a diameter of 150 mm, 200 mm, 300 mm, or 450 mm.

An array of the via cavities 201 may be formed in the upper portion of the semiconductor material layer 202, for example, by a photolithographic process. The photolithographic process may include, for example, forming an etch mask layer including a hard mask material (such as borosilicate glass) on the semiconductor material layer 202, patterning the etch mask layer with patterns of arrays of discrete openings, and transferring the pattern in the etch mask layer into an upper portion of the semiconductor material layer 202. The depth of the via cavities 201 in the intermediate structure may be in a range from 1 micron to 100 microns although lesser and greater depths may also be used. In one embodiment, the pattern of the array of via cavities 201 may have a two-dimensional periodicity over the semiconductor material layer 202.

The insulating liner 203 (e.g., silicon oxide) may then be formed on the sidewalls of the via cavities 201 and over the top surface of the semiconductor material layer 202 (e.g., silicon wafer). The insulating liner 203 may be formed by depositing (e.g., by CVD, PVD or other suitable deposition technique) a layer of insulating material on the semiconductor material layer 202. The insulating material may be deposited so as to be conformally formed on the sidewalls of the via cavities 201, so that openings O₂₀₄ bounded by the insulating liner 203 on the sidewalls of the via cavities 201 may be formed in the via cavities 201.

Another photolithographic process may be performed to form one or more openings O₅₀₀ in the insulating liner 203 and the semiconductor material layer 202. The openings O₅₀₀ may located in the dummy via formation region 510. In particular, a location of the openings O₅₀₀ may correspond to a location of the dummy vias 500 (see FIG. 1D). Thus, a precise placement of the openings O₅₀₀ may be determined based on an anticipated location of the first semiconductor die 141 on the interposer 200. In particular, the placement of the openings O₅₀₀ may be determined based on an anticipated location of the sidewalls S₁₄₁ of the first semiconductor die 141.

A depth of the openings O₅₀₀ may be substantially equal to the thickness T_{V} of the dummy vias 500. The photolithographic process may include, for example, forming an etch mask layer including a hard mask material (such as borosilicate glass) on the insulating liner 203, patterning the etch mask layer with discrete openings, and transferring the pattern in the etch mask layer into an upper portion of the insulating liner 203 and the semiconductor material layer 202.

FIG. 2B is a vertical cross-sectional view of an intermediate structure including the TSVs 204 and dummy vias 500 in the semiconductor material layer 202 according to one or more embodiments. The TSVs 204 may be formed in the openings O₂₀₄ in the via cavities 204 by depositing one or more layers of conductive material (e.g., metallic barrier material (TiN, TaN, WN, MON, TiC, TaC, WC, etc.), metallic fill material (Cu, Co, Ru, Mo, W, etc.), etc.) in the openings O₂₀₄. The dummy vias 500 may be formed concurrently (e.g., using the same deposition process) with the forming of the TSVs 204 by depositing the one or more layers of conductive material in the openings O₅₀₀. In such an embodiment, the TSVs 204 and the dummy vias 500 may be formed of substantially the same material. The dummy vias 500 may alternatively be formed before or after the forming of the TSVs 204 using a different deposition process.

The one or more layers of conductive material may be deposited, for example, by CVD, PVD or other suitable deposition technique. A planarization process such as a chemical mechanical polishing (CMP) process and/or a recess etch process may then be performed to remove any excess amount of the conductive material from above the horizontal plane including the top surface of the horizontally-extending portion of the insulating liner 203. The upper surface of the TSVs 204 may thereby be made to be substantially coplanar with the upper surface of the insulating liner 203.

It should be noted that the openings O₅₀₀ may alternatively be formed in the semiconductor material layer 202 prior to the forming of the via cavities 201 or concurrently with the forming of the via cavities 201. In that case, an upper surface of the dummy vias 500 may be planarized (e.g., by CMP, etc.) to be substantially coplanar with an upper surface of the semiconductor material layer 202.

FIG. 2C is a vertical cross-sectional view of an intermediate structure including the bonding layer 13 and upper bonding pads 13a according to one or more embodiments. The upper bonding pads 13a may be formed by depositing (e.g., by CVD, PVD or other suitable deposition technique) one or more metal layers including a metal, metal alloys, and/or other metal-containing compounds (e.g., Cu, Al, Mo, Co, Ru, W, TiN, TaN, WN, etc.) on the interposer 200. In particular, the one or more metal layers may be deposited on the upper surface of the insulating liner 203 and the upper surface of the TSVs 204. The metal layer(s) may then be patterned by a photolithographic process so as to form the upper bonding pads 13a in contact with the the TSVs 204 in the interposer 200. The photolithographic process may include forming a patterned photoresist mask (not shown) on the metallic material, and etching (e.g., wet etching, dry etching, etc.) the exposed upper surface of the metallic material through openings in the photoresist mask. The photoresist mask may be subsequently removed by ashing, dissolving the photoresist mask or by consuming the photoresist mask during the etch process.

In at least one embodiment, the upper bonding pads 13a may include an underbump metallurgy (UBM) layer stack. The order of material layers within the UBM layer stack may be selected such that solder material portions may be subsequently bonded to portions of the UBM layer stack. Layer stacks that may be used for the UBM layer stack include, but are not limited to, stacks of Cr/Cr-Cu/Cu/Au, Cr/Cr-Cu/Cu, TiW/Cr/Cu, Ti/Ni/Au, and Cr/Cu/Au. Other suitable materials are within the contemplated scope of disclosure. The thickness of the UBM layer stack may be in a range from 5 microns to 60 microns, such as from 10 microns to 30 microns, although lesser and greater thicknesses may also be used. A photoresist layer may be applied over the UBM layer stack, and may be lithographically patterned to form an array of discrete patterned photoresist material portions. An etch process may be performed to remove unmasked portions of the UBM layer stack. The etch process may be an isotropic etch process or an anisotropic etch process. Remaining portions of the UBM layer stack may form the upper bonding pads 13a. In at least one embodiment, the upper bonding pads 13a may be arranged as a two-dimensional array, which may be a two-dimensional periodic array such as a rectangular periodic array.

The bonding layer 13 may then be formed on the interposer 200 over the upper bonding pads 13a. The bonding layer 13 may be formed by depositing (e.g., by CVD, PVD or other suitable deposition technique) one or more layers of dielectric material such as silicon oxide, low-k dielectric materials such as carbon-doped oxides, extremely low-k dielectric materials such as porous carbon doped silicon dioxide, a combination thereof or other suitable material. The dielectric material may then be planarized (e.g., by wet etching, drying etching, etc.) until the upper bonding pads 13a are exposed. The bonding layer 13 may, thus, be formed to have an upper surface that is substantially coplanar with an upper surface of the upper bonding pads 13a.

FIG. 2D is a vertical cross-sectional view of an intermediate structure including the first semiconductor die 141 and the second semiconductor die 142 according to one or more embodiments. The first semiconductor die 141 and second semiconductor die 142 may be placed on bonding layer 13, for example, by using a electromechanical pick-and-place (PNP) machine. As illustrated in FIG. 2D, the first semiconductor die 141 may be positioned on the bonding layer 13 so that the sidewall S₁₄₁ of the first semiconductor die 141 is substantially aligned with the dummy via 500 (e.g., a center of the dummy via 500).

A hybrid bonding process may be performed to bond the first semiconductor die 141 and the second semiconductor die 142 to the interposer 200. The hybrid bonding process may form, for example, a metal-metal bond between the die bonding pads 155 and the upper bonding pads 13a. The hybrid bonding process may also form, for example, an oxide-oxide bond between the die bonding layer 153 and the bonding layer 13. It should be noted that the hybrid bonding process may utilize less than all of the die bonding pads 155, less than all of the upper bonding pads 13a, less than all of the bonding layer 13 and less than all of the die bonding layer 153.

The hybrid bonding process may optionally include, for example, a surface preparation step in which a surface of the semiconductor dies 140 and a surface of the bonding layer 13 are prepared by cleaning and removing any contaminants or oxides that could interfere with bonding. The surface preparation step may help to achieve optimal bonding quality. An alignment step may be performed in which the semiconductor dies 140 and the interposer 200 are more precisely aligned to help ensure accurate positioning of the interconnects. The alignment step may be performed, for example, using alignment marks or an optical alignment system. Once aligned, the semiconductor dies 140 and the interposer 200 may be brought into close contact. The bonding process may be performed at room temperature (room-temperature bonding) or at elevated temperatures (thermal bonding) depending on the specific bonding technique used.

In the bonding process, the die bonding layer 153 and the bonding layer 13 may be activated to form a chemical bond (e.g., oxide-oxide bond) at the atomic level. In at least one embodiment, oxide layers in the die bonding layer 153 and the bonding layer 13 may be brought into contact, allowing oxygen atoms to migrate therebetween and form covalent bonds. In at least one embodiment, elevated temperature and pressure may be applied to form the oxide-oxide bond. Concurrently with the formation of the oxide-oxide bond, a metal-metal bond may be formed between the metal layers of the die bonding pads 155 and the upper bonding pads 13a. In at least one embodiment, elevated temperature and pressure may be applied to form the metal-metal bond through diffusion or solid-state reactions.

FIG. 2E is a vertical cross-sectional view of an intermediate structure including the molding material layer 127 according to one or more embodiments. The molding material layer 127 may be formed by dispensing a liquid molding material (e.g., epoxy molding material) onto the intermediate structure of FIG. 2D by a suitable dispensing tool. The molding material layer 127 may be dispensed onto the intermediate structure so as to have a height greater than a height of the upper surface of the semiconductor dies 140.

In at least one embodiment, a dispensing of the molding material may be automated. In particular, various aspects of the dispensing process may be computer-controlled by a control system (e.g., electronic control system; central processing unit (CPU)). In at least one embodiment, a beginning of the dispensing of the molding material, a flow rate of the dispensing of the molding material, and a stopping of the dispensing of the molding material may be controlled by the control system. The control system may be programmed, for example, to dispense a predetermined amount of the molding material based on various input parameters. The input parameters may include, for example, a volume of the space around the bonding layer 13, a size of the semiconductor dies 140, etc.

In at least one embodiment, the molding material of the molding material layer 127 may include a capillary material (e.g., capillary underfill type material). The molding material may have a low viscosity. In particular, the viscosity may be less than about 5,000 cP at 10 rpm. In at least one embodiment, the molding material may include a low-viscosity suspension of thermally conductive material (e.g., metal, metal oxide) in prepolymer. The low viscosity may help to facilitate transport of the molding material around the semiconductor dies 140. The low viscosity may also help to avoid the formation of voids in the molding material layer 127. In at least one embodiment, the molding material layer 127 may be substantially free of voids.

After the molding material layer 127 has been adequately cured, the molding material layer 127 may be planarized so as to make the upper surface of the molding material layer 127 to be substantially coplanar with the upper surface of the semiconductor dies 140. The molding material layer 127 may be planarized, for example, by grinding, chemical mechanical polishing (CMP) or other suitable planarization techniques.

FIG. 2F is a vertical cross-sectional view of an intermediate structure after the thinning of the semiconductor material layer 202 according to one or more embodiments. After the planarizing of the molding material layer 127, a carrier substrate 300 (e.g., carrier wafer) may be attached to an upper surface of the intermediate structure of FIG. 2E. The carrier substrate 300 may include, for example, a circular wafer or a rectangular wafer. The lateral dimensions (such as the diameter of a circular wafer or a side of a rectangular wafer) of the carrier substrate 300 may be in a range from 100 mm to 500 mm, such as from 200 mm to 400 mm, although lesser and greater lateral dimensions may also be used. The carrier substrate 300 may include a semiconductor substrate, an insulating substrate, or a conductive substrate. The carrier substrate 300 may be transparent or opaque. The thickness of the carrier substrate 300 may be sufficient to provide mechanical support to an array of interposers to be formed thereupon. For example, the thickness of the carrier substrate 300 may be in a range from 60 microns to 1 mm, although lesser and greater thicknesses may also be used.

An adhesive layer (not shown) may be applied to the top surface of the carrier substrate 300. In one embodiment, the carrier substrate 300 may include an optically transparent material such as glass or sapphire. In this embodiment, the adhesive layer may include a light-to-heat conversion (LTHC) layer. The LTHC layer is a solvent-based coating applied using a spin coating method. The LTHC layer may form a layer that converts ultraviolet light to heat such that the LTHC layer loses adhesion. Alternatively, the adhesive layer may include a thermally decomposing adhesive material. For example, the adhesive layer may include an acrylic pressure-sensitive adhesive that decomposes at an elevated temperature. The debonding temperature of the thermally decomposing adhesive material may be in a range from 150° C. to 400° C. Other suitable thermally decomposing adhesive materials that decompose at other temperatures are within the contemplated scope of disclosure.

After the carrier substrate 300 is attached to the upper surface of the intermediate structure, the intermediate structure may be flipped (e.g., inverted). A backside surface of the semiconductor material layer 202 (e.g., silicon wafer) may then be thinned by performing a polishing process. In at least one embodiment, the semiconductor material layer 202 may be thinned by performing a CMP process. The polishing process may be performed until a bottom surface 204a of the TSVs 204 is exposed.

The backside surface of the semiconductor material layer 202 may then be vertically recessed, for example, by performing an isotropic etch process that removes silicon selective to the insulating liner 203 and the TSVs 204. In an illustrative example, a wet etch process using potassium hydroxide may be performed to vertically recess the backside surface of the semiconductor material layer 202 by a vertical recess distance. The vertical recess distance may be in a range from 100 nm to 500 nm, although lesser and greater vertical recess distances may also be used.

The lower insulating layer 205 may then be formed on the recessed backside surface of the semiconductor material layer 202. The lower insulating layer 205 may be formed, for example, by depositing an insulating material such as silicon oxide on the recessed backside surface of the semiconductor material layer 202. The thickness of the lower insulating layer 205 may be about the same as, or may be greater than, the vertical recess distance of the backside silicon surface of the semiconductor material layer 202. A planarization process, such as a polishing process, may then be performed to remove portions of the lower insulating layer 205, and to make a surface of the lower insulating layer 205 to be coplanar with the bottom surface 204a of the TSVs.

FIG. 2G illustrates a vertical cross-sectional view of an intermediate structure including the plurality of C4 bumps 121, according to one or more embodiments. The plurality of C4 bumps 121 may be formed so as to contact the bottom surface 204a of the TSVs 204. The C4 bumps 121 may be formed by forming the metal pillar 121a (e.g., copper pillar) on the bottom surface 204a, for example, by an electroplating process. The solder bump 121b may then be formed on the metal pillar 121a by a suitable process (e.g., deposition, electroplating, etc.).

In at least one embodiment, a bonding pad (not shown) may be formed on the bottom surface 204a of the TSVs, and the C4 bumps 121 may be formed on the bonding pad. In at least one embodiment, one or more underbump metallization (UBM) layers (not shown) may be formed on the bottom surface 204a of the TSVs 204 (or the bonding pad, if present), and the metal pillar 121a may be formed on the UBM layers. That is, the C4 bump 121 may be formed so as to contact the TSVs 204 through the UBM layers and/or the bonding pad.

After the C4 bumps 121 are formed, the carrier substrate 300 may be detached from the intermediate structure. In some embodiments, the carrier substrate 300 and the adhesive layer (not shown) may be removed by backside grinding. Alternatively, the carrier substrate 300 includes an optically transparent material and the adhesive layer includes a light-to-heat conversion material, and irradiation through the carrier substrate 300 may be used to detach the carrier substrate 300. If the adhesive layer includes a thermally decomposable adhesive material, an anneal process or a laser irradiation may be used to detach the carrier substrate 300. A suitable clean process may be performed to remove residual portions of the adhesive layer.

In at least one embodiment, a plurality of the package modules 120 may be formed concurrently in a wafer-level process. In that case, after the forming of the C4 bumps 121, a singulation process may be performed in order to singulate the package modules 120. The singulation process may be performed, for example, by using a dicing saw to saw the interposer 200 (e.g., and the molding material 127 formed thereon) along dicing lines. The dicing lines may be located around the entire periphery of the semiconductor dies 140. In at least one embodiment, the dicing lines may be located so as to allow a sufficient distance DE between the dummy via formation region 510 and the outer sidewall of the package module 120 (e.g., outer sidewall of the molding material layer 127). In at least one embodiment, the distance DE between the dummy via formation region 510 and the outer sidewall of the package module 120 may be in a range from 0.5 mm to 5 mm.

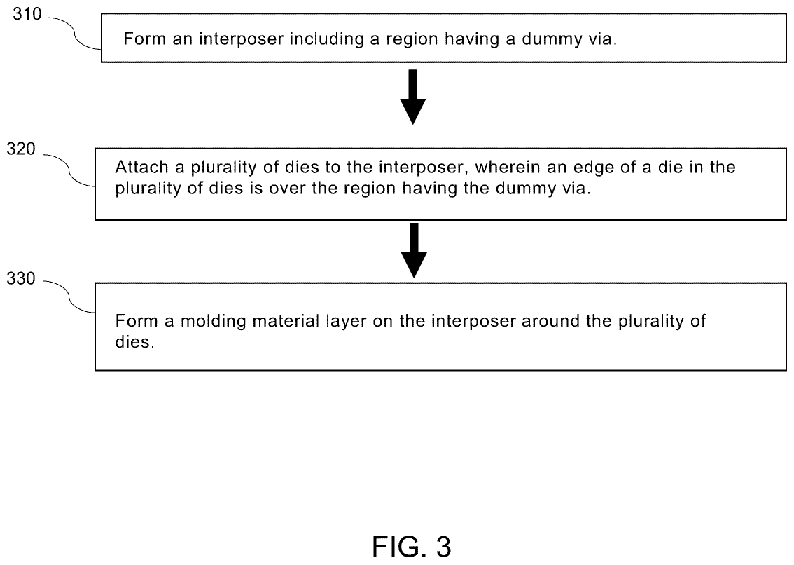

FIG. 3 is a flow chart illustrating a method of forming a package module according to one or more embodiments. With reference to FIGS. 2A, 2B, and 3, step 310 includes forming an interposer including a region having a dummy via 500. With reference to FIGS. 2D and 3, step 320 includes attaching a plurality of dies 140 to the interposer 200, wherein an edge of a semiconductor die 140 in the plurality of semiconductor dies 140 is over the region having the dummy via 500. With reference to FIGS. 2E and 3, step 330 includes forming a molding material layer 127 on the interposer around the plurality of semiconductor dies 140.

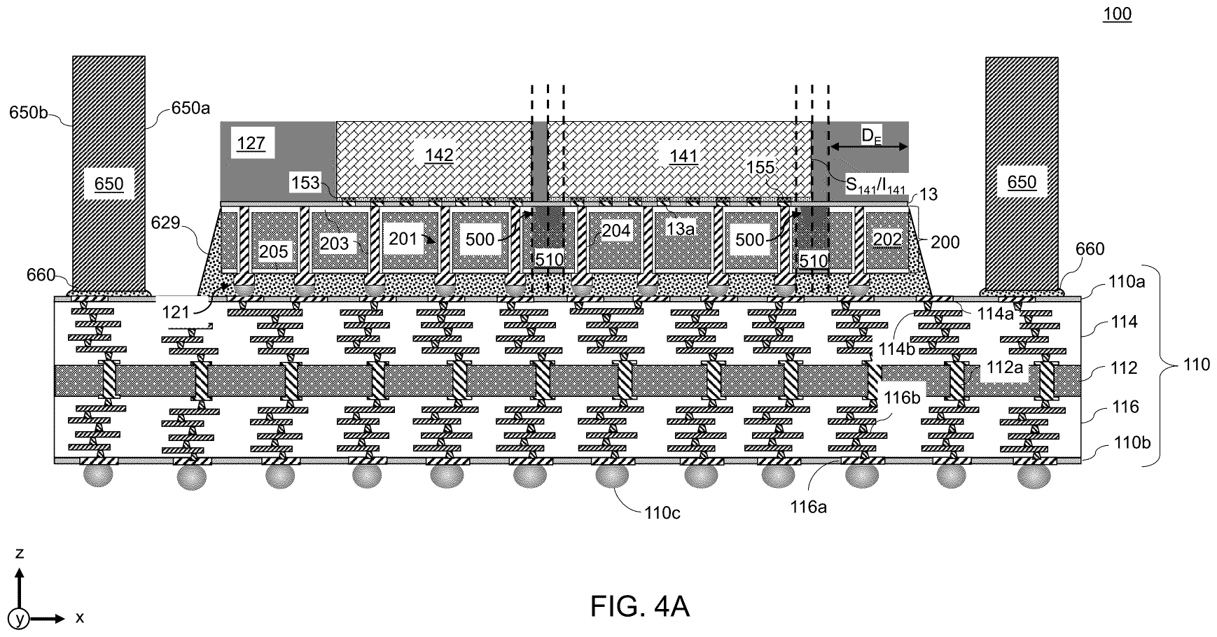

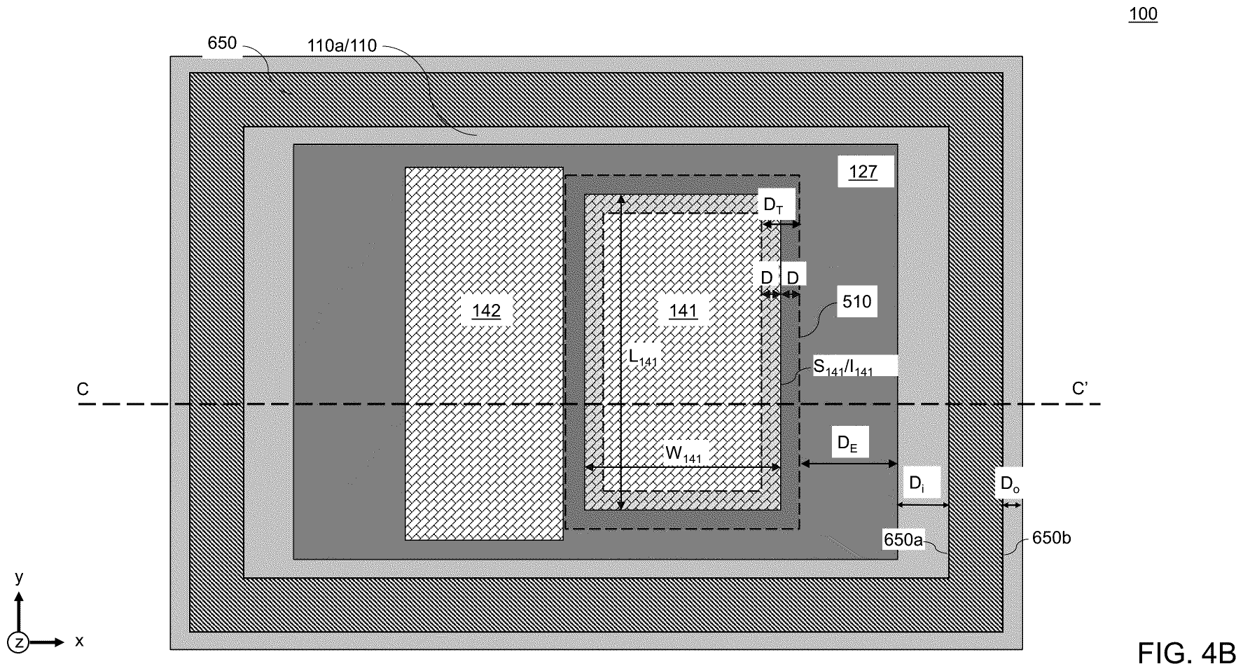

FIGS. 4A-4B illustrate a package structure 100 including the package module 120, according to one or more embodiments. FIG. 4A is a vertical cross-sectional view of the package structure 100 including the package module 120, according to one or more embodiments. FIG. 4B is a plan view (e.g., top-down view) of the package structure 100 including the package module 120, according to one or more embodiments. The vertical cross-sectional view in FIG. 4A is along the line C-C′ in FIG. 4B.

Generally, the package structure 100 may include a package substrate 110, the package module 120 on the package substrate 110, and a stiffener ring 650 adhered and/or affixed to the package substrate 110 adjacent to the package module 120. The stiffener ring 650 may include an inner edge 650a and an outer edge 650b.

The package substrate 110 may include, for example, a core 112, a package substrate upper dielectric layer 114 formed on the core 112 (e.g., a first side or chip-side of the package substrate 110), and a package substrate lower dielectric layer 116 formed on the core 112 (e.g., a second side or board-side of the package substrate 110). In particular, the package substrate 110 may include a build-up film substrate such as an Ajinomoto build-up film (ABF) substrate. That is, in at least one embodiment, each of the package substrate upper dielectric layer 114 and the package substrate lower dielectric layer 116 may be described as an ABF layer.

The core 112 may help to provide rigidity to the package substrate 110. The core 112 may include, for example, an epoxy resin such as a bismaleimide triazine epoxy (BT epoxy) and/or a woven glass laminate. The core 112 may alternatively or in addition include an organic material such as a polymer material. In particular, the core 112 may include a dielectric polymer material such as polyimide (PI), benzocyclo-butene (BCB), or polybenzobisoxazole (PBO). Other suitable dielectric materials are within the contemplated scope of disclosure.

The core 112 may include one or more through vias 112a. The through vias 112a may extend from a lower surface of the core 112 to an upper surface of the core 112. The through vias 112a may allow an electrical connection between the package substrate upper dielectric layer 114 and the package substrate lower dielectric layer 116. The through vias 112a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate upper dielectric layer 114 may be formed on an upper surface of the core 112. The package substrate upper dielectric layer 114 may include a plurality of layers and, in particular, may include an Ajinomoto build-up film (e.g., ABF). The package substrate upper dielectric layer 114 may also include an organic material such as a polymer material. In particular, the package substrate upper dielectric layer 114 may include a dielectric polymer material such as polyimide (PI), benzocyclobutene (BCB), or polybenzobisoxazole (PBO). Other suitable dielectric materials are within the contemplated scope of disclosure.

The package substrate upper dielectric layer 114 may include one or more package substrate upper bonding pads 114a on a chip-side surface of the package substrate upper dielectric layer 114. In particular, the package substrate upper bonding pads 114a may be exposed on the chip-side surface of the package substrate upper dielectric layer 114. The package substrate upper dielectric layer 114 may also include one or more metal interconnect structures 114b. The metal interconnect structures 114b may be connected to the package substrate upper bonding pads 114a and the through vias 112a in the core 112. The metal interconnect structures 114b may include metal layers (e.g., copper traces) and metal vias connecting the metal layers. The package substrate upper bonding pads 114a and the metal interconnect structures 114b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

An upper passivation layer 110a may be formed on the chip-side surface of the package substrate upper dielectric layer 114. The upper passivation layer 110a may partially cover the package substrate upper bonding pads 114a. The upper passivation layer 110a may include silicon oxide, silicon nitride, low-k dielectric materials such as carbon-doped oxides, extremely low-k dielectric materials such as porous carbon doped silicon dioxide, a combination thereof or other suitable material.

The package substrate lower dielectric layer 116 may be formed on an lower surface of the core 112. The package substrate lower dielectric layer 116 may also include a plurality of layers and, in particular, may include a build-up film (e.g., ABF). The package substrate lower dielectric layer 116 may also include an organic material such as a polymer material. In particular, the package substrate lower dielectric layer 116 may include a dielectric polymer material such as polyimide (PI), benzocyclobutene (BCB), or polybenzobisoxazole (PBO). Other suitable dielectric materials are within the contemplated scope of disclosure.

The package substrate lower dielectric layer 116 may include one or more package substrate lower bonding pads 116a on a board-side surface of the package substrate lower dielectric layer 116. In particular, the package substrate lower bonding pads 116a may be exposed on the chip-side surface of the package substrate lower dielectric layer 116. The package substrate lower dielectric layer 116 may also include one or more metal interconnect structures 116b. The metal interconnect structures 116b may be connected to the package substrate lower bonding pads 116a and the through vias 112a in the core 112. The metal interconnect structures 116b may include metal layers (e.g., copper traces) and metal vias connecting the metal layers. The package substrate upper bonding pads 116a and the metal interconnect structures 116b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A lower passivation layer 110b may be formed on the board-side surface of the package substrate lower dielectric layer 116. The lower passivation layer 110b may partially cover the package substrate lower bonding pads 116a. The lower passivation layer 110a may include silicon oxide, silicon nitride, low-k dielectric materials such as carbon-doped oxides, extremely low-k dielectric materials such as porous carbon doped silicon dioxide, a combination thereof or other suitable material.

In at least one embodiment, the package substrate lower dielectric layer 116 may also include one or more package substrate dummy vias (not shown). The package substrate dummy vias may be formed in the board-side surface of the package substrate lower dielectric layer 116 and may or may not be exposed at the board-side surface of the package substrate lower dielectric layer 116. The package substrate dummy vias may be substantially aligned with an edge of the stiffener ring 650. In particular, a centerline in the x-direction of the package substrate dummy vias may be substantially aligned with the inner edge 650a of the stiffener ring 650. A lowermost surface of the package substrate dummy vias may be substantially coplanar with the lowermost surface of the package substrate lower bonding pads 116a and with the board-side surface of the package substrate lower dielectric layer 116. The package substrate dummy vias may be exposed at the board-side surface of the package substrate lower dielectric layer 116, or may be covered by another layer of the package substrate 110 such as the lower passivation layer 110b. The package substrate dummy vias may provide rigidity to the package substrate 110.

A ball-grid array (BGA) including a plurality of solder balls 110c may be formed on the board-side surface of the package substrate lower dielectric layer 116. The solder balls 110c may allow the package structure 100 to be securely mounted on a substrate such as a printed circuit board (PCB) and electrically coupled to the PCB substrate. The solder balls 110c may contact the package substrate lower bonding pads 116a, respectively. The solder balls 110c may therefore be electrically connected to the package substrate upper bonding pads 114a by way of metal interconnect structures 116b, the through vias 112a and the metal interconnect structures 114b. The solder balls 110c of the BGA may be located under the stiffener ring 650 and under the package module 120.

The package module 120 may be attached by the C4 bumps 121 to the package substrate upper bonding pads 114a in the package substrate 110. In particular, the solder bump portion of the C4 bump 121 may be collapsed to join the pillar portion of the C4 bump 121 to the package substrate upper bonding pads 114a. A package underfill layer 629 may be formed on the package substrate 110, under and around the package module 120 and around the C4 bumps 121. The package underfill layer 629 may help to securely fix the package module 120 to the package substrate 110. The package underfill layer 629 may be formed of an epoxy-based polymeric material.

The stiffener ring 650 may be attached to the package substrate 110 around the package module 120. The stiffener ring 650 may be securely fixed to the package substrate 110 by an adhesive 660 (e.g., a silicone adhesive or an epoxy adhesive). The stiffener ring 650 may be formed of a metal such as copper with a nickel coating, or an aluminum alloy. The stiffener ring 650 may provide rigidity to the package substrate 110.

Referring again to the plan view in FIG. 4B, a location of the stiffener ring 650 in relation to the package module 120 is illustrated. The stiffener ring 650 may be located around an entire periphery of the package module 120. The inner edge 650a of the stiffener ring 650 may be separated from the outer sidewall of the package module 120 (e.g., outer sidewall of the molding material layer 127 and/or outer sidewall of the interposer 200) by an inner distance Di. In at least one embodiment, the inner distance Di may be less than the distance DE between the dummy via formation region 510 and the outer sidewall of the package module 120. In at least one embodiment, the inner distance Di may be in a range from 0.1 mm to 4 mm. As illustrated in FIG. 4B, the inner distance Di may be greater in a longitudinal direction of the package module 120 (e.g., the x-direction in FIG. 4B) than in a direction perpendicular to the longitudinal direction of the package module 120. Alternatively, the inner distance Di may be substantially uniform around the periphery of the package module 120.

The outer edge 650b of the stiffener ring 650 may be separated from an edge of the package substrate 110 by an outer distance Do. In at least one embodiment, the outer distance Do may be less than the inner distance Di between the inner edge 650a of the stiffener ring 650 and the outer sidewall of the package module 120 (e.g., outer sidewall of the molding material layer 127 and/or outer sidewall of the interposer 200). In at least one embodiment, the outer distance Do may be in a range from 0.05 mm to 2 mm. In at least one embodiment, the outer distance Do may be substantially uniform around the periphery of the stiffener ring 650.

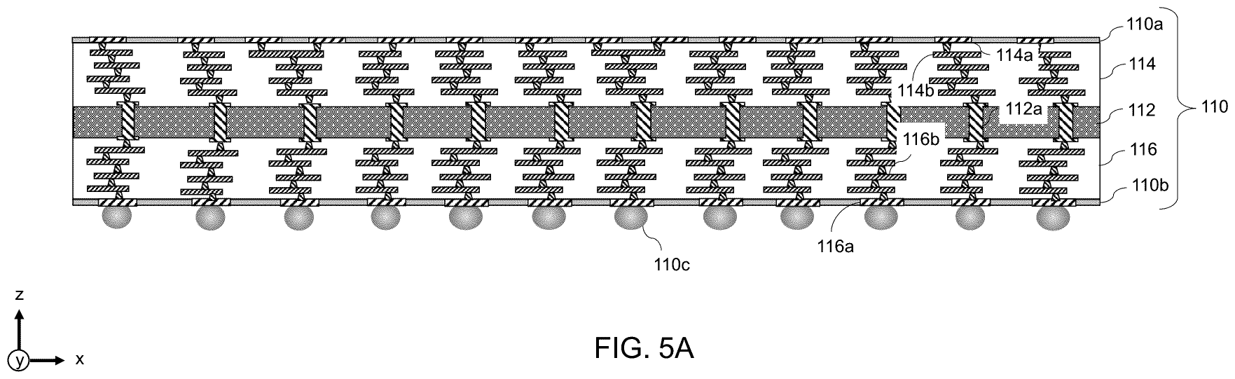

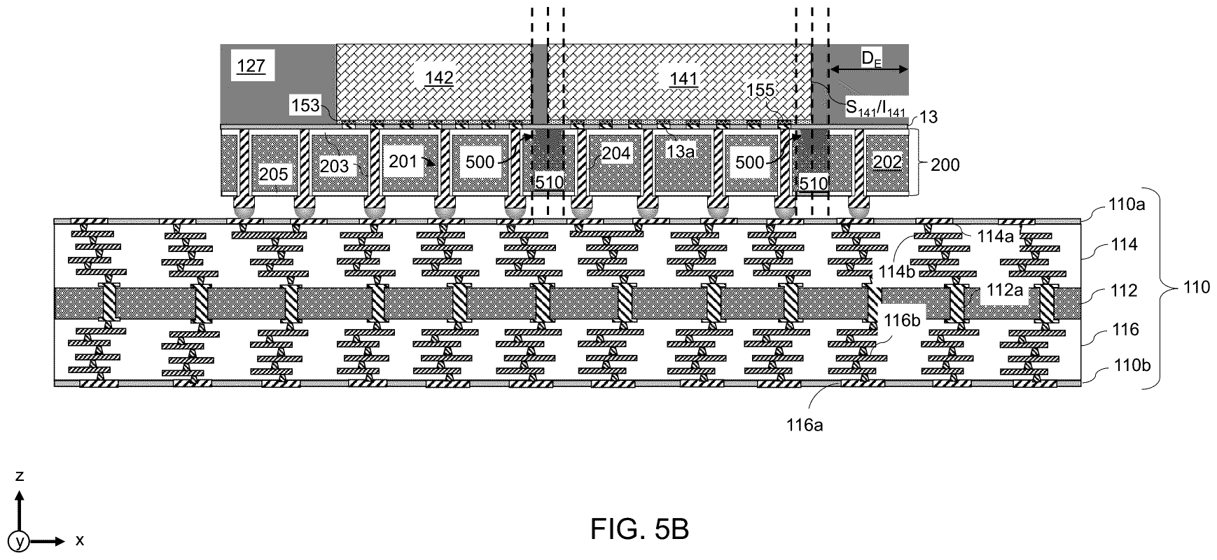

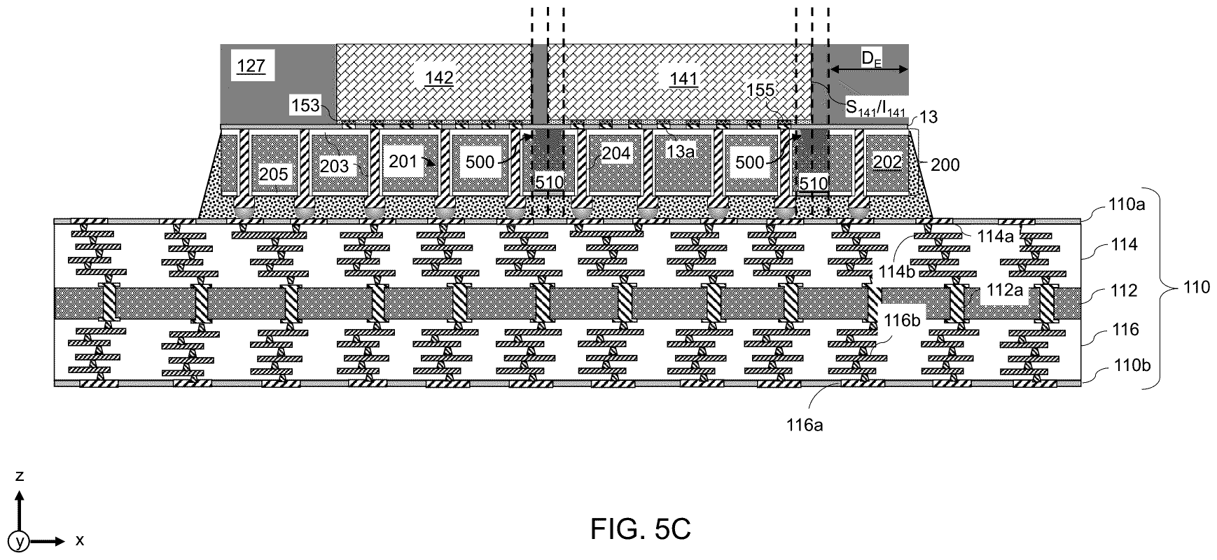

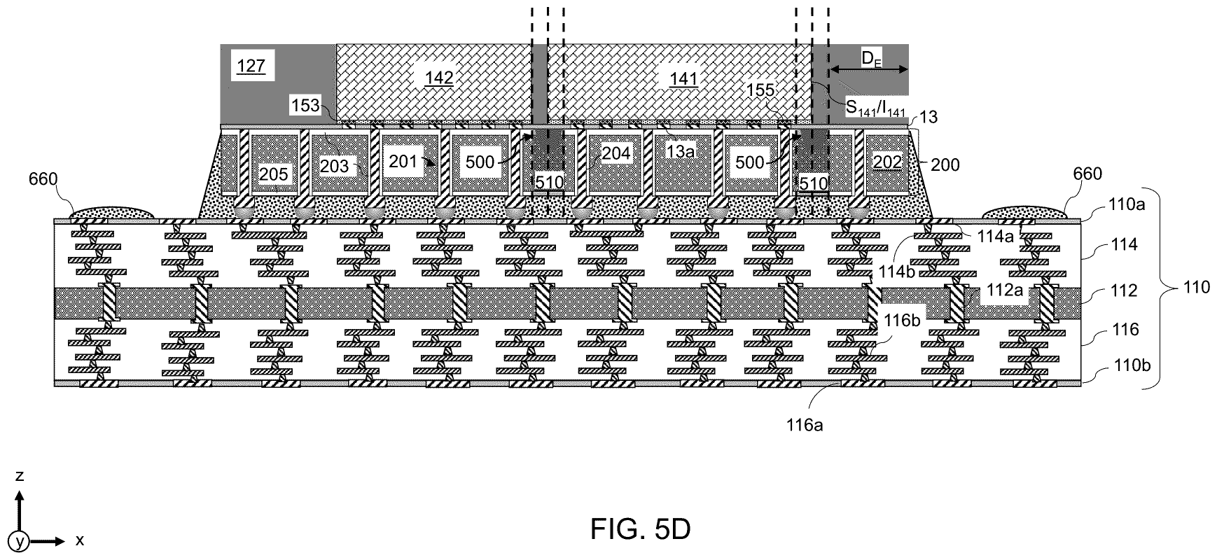

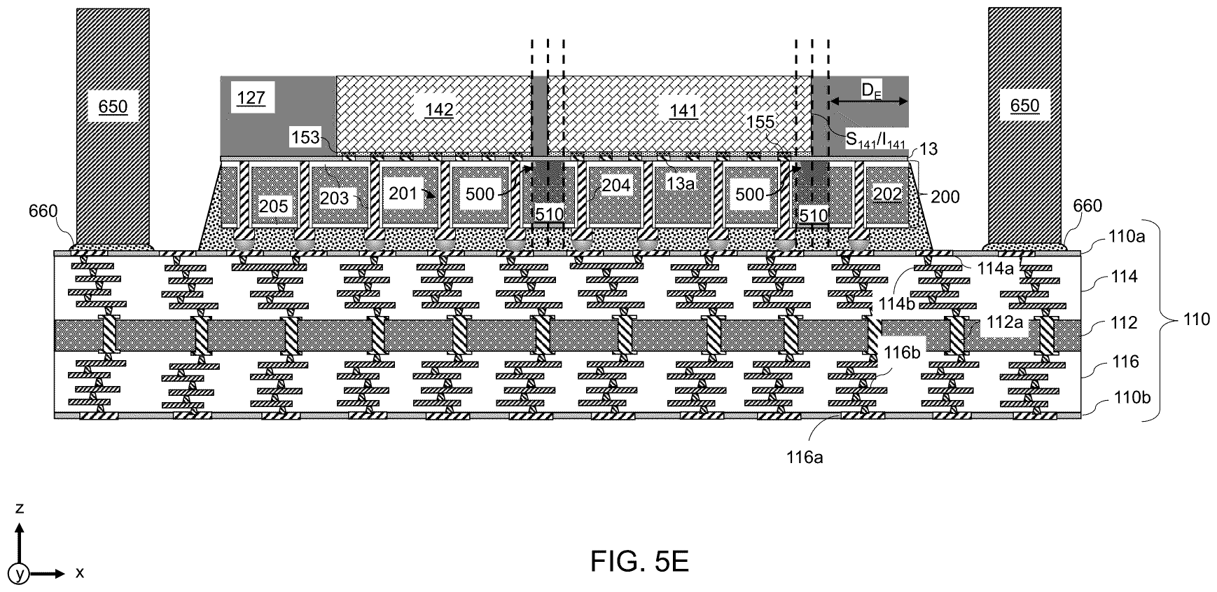

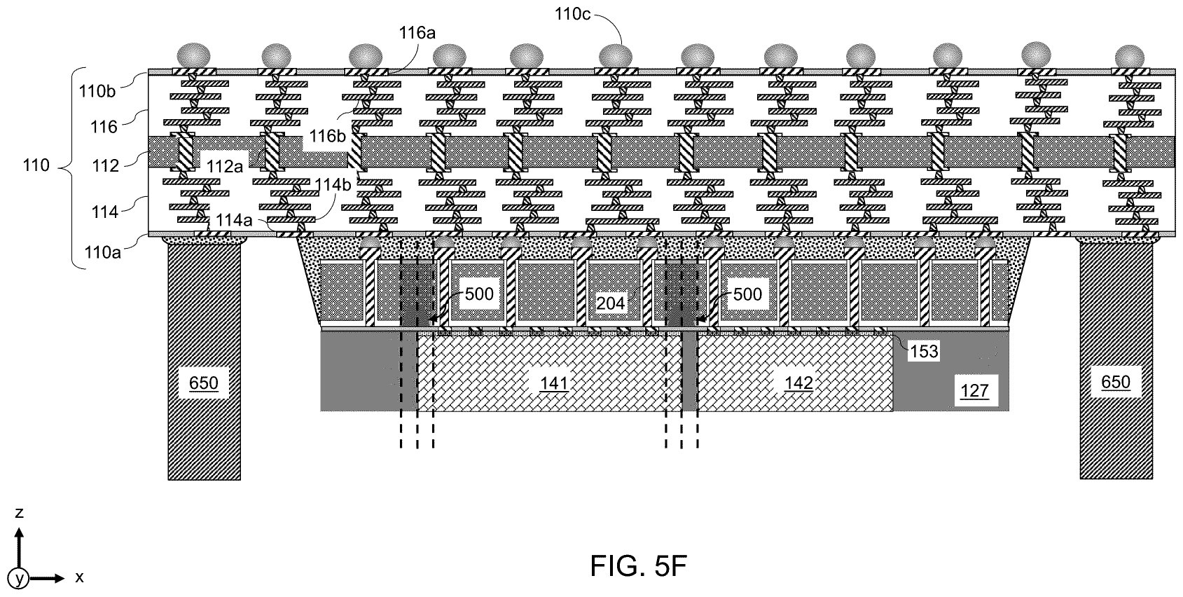

FIGS. 5A-5F illustrate various intermediate structures in a method of forming the package structure 100 according to one or more embodiments. FIG. 5A is a vertical cross-sectional view of an intermediate structure including the package substrate 110 having package substrate upper bonding pads 114a and package substrate lower bonding pads 116a, according to one or more embodiments. The package substrate 110 including the core 112, the package substrate upper dielectric layer 114, and the package substrate lower dielectric layer 116 may be provided.

The package substrate upper bonding pads 114a may be formed, for example, on an uppermost dielectric layer of the package substrate upper dielectric layer 114. The package substrate upper bonding pads 114a may be formed to contact the metal interconnect structures 114b. The package substrate upper bonding pads 114a may be formed by depositing a metal layer (e.g., copper, aluminum or other suitable conductive materials) on the upper surface of the package substrate upper dielectric layer 114. The metal layer may then be patterned by etching (e.g., by wet etching, dry etching, etc.) to form the package substrate upper bonding pads 114a. Other suitable metal layer materials and etching processes may be within the contemplated scope of disclosure.

The package substrate lower bonding pads 116a may be formed, for example, on a lowest dielectric layer of the package substrate lower dielectric layer 116. The package substrate lower bonding pads 116a may be formed to contact the metal interconnect structures 116b. The package substrate lower bonding pads 116a may be formed in a manner similar to the manner of forming the package substrate upper bonding pads 114a (e.g., depositing a metal layer, patterning the metal layer by etching, etc.).

After formation, the package substrate upper bonding pads 114a and package substrate lower bonding pads 116a may optionally undergo a surface roughening treatment (e.g., copper zarazara (CZ) treatment). In the surface roughening treatment, a surface of the package substrate upper bonding pads 114a (e.g., a copper surface) and surface of the package substrate lower bonding pads 116a (e.g., a copper surface) may be etched by an organic acid-type microetching solution, to create a super-roughened surface (e.g., copper surface). The uniquely-roughened copper surface topography of the package substrate upper bonding pads 114a and package substrate lower bonding pads 116a may help to achieve a high copper-to-resin adhesion.

The package substrate upper passivation layer 110a and package substrate lower passivation layer 110b may then be formed on the package substrate upper bonding pads 114a and package substrate lower bonding pads 116a, respectively. In at least one embodiment, the package substrate upper passivation layer 110a may include a solder resist layer (e.g., polymer material), also referred to as a solder mask. The package substrate upper passivation layer 110a may also be referred to as the upper solder resist layer 110a, and the package substrate lower passivation layer 110b may also be referred to as the lower solder resist layer 110b.

The package substrate upper passivation layer 110a and package substrate lower passivation layer 110b may be applied concurrently. The package substrate upper passivation layer 110a and package substrate lower passivation layer 110b may be applied, for example, as a liquid photo-imagable film. The liquid photo-imagable film can be applied, for example, by silk-screening or spraying the liquid photo-imagable film onto the surface of the package substrate 110. The liquid photo-imagable film may be applied over the package substrate upper bonding pads 114a and the package substrate lower bonding pads 116a. The package substrate upper passivation layer 110a and package substrate lower passivation layer 110b may alternatively be applied as a dry-film photo-imagable film that may be vacuum-laminated onto the surface of the package substrate 110 and over the package substrate upper bonding pads 114a and package substrate lower bonding pads 116a, respectively. The package substrate upper passivation layer 110a and package substrate lower passivation layer 110b may alternatively or additionally be formed, for example, by chemical vapor deposition (CVD), physical vapor deposition (PVD), spin coating, lamination or other suitable deposition technique.

As illustrated in FIG. 5A, the package substrate upper passivation layer 110a and package substrate lower passivation layer 110b may be applied so as to have an upper surface that is substantially coplanar with an upper surface of the package substrate upper bonding pads 114a and package substrate lower bonding pads 116a, respectively. Alternatively, the package substrate upper passivation layer 110a and package substrate lower passivation layer 110b may be applied to have a thickness that is slightly greater than a thickness of the package substrate upper bonding pads 114a and package substrate lower bonding pads 116a, respectively. In that case, openings (not shown) may be formed (e.g., by etching (e.g., wet etching, dry etching, etc.) in a photolithographic process) in the package substrate upper passivation layer 110a and in the package substrate lower passivation layer 110b to expose the package substrate upper bonding pads 114a and package substrate lower bonding pads 116a, respectively.

FIG. 5B illustrates a vertical cross-sectional view of an intermediate structure in which the package module 120 may be attached to the package substrate 110, according to one or more embodiments. The package module 120 may be attached to the package substrate 110, for example, by a flip chip bonding (FCB) process. In the FCB process, the package module 120 may be positioned over the package substrate 110, for example, by an electromechanical pick-and-place (PNP) machine. The C4 bumps 121 on the package module 120 may be lowered onto the package substrate upper bonding pads 114a of the package substrate 110 and heated in order to collapse the C4 bumps 121 and bond the C4 bumps 121 to the package substrate upper bonding pads 114a.

FIG. 5C illustrates a vertical cross-sectional view of an intermediate structure in which the package underfill layer 629 may be formed on the package substrate 110 according to one or more embodiments. As illustrated in FIG. 5C, the package underfill layer 629 (e.g., epoxy-based polymeric material) may be dispensed (e.g., injected) onto the package substrate 110, under and around the package module 120 and around the C4 bumps 121. The package underfill layer 629 may then be cured, for example, in a box oven for duration in a range from 60 minutes to 120 minutes at a temperature in a range from 120° C. to 180° C. to provide the package underfill layer 629 with a sufficient stiffness and mechanical strength.

FIG. 5D illustrates a vertical cross-sectional view of an intermediate structure in which the adhesive layer 660 may be applied to the package substrate 110 according to one or more embodiments. The adhesive layer 660 may be dispensed onto the package substrate 110 with a dispensing tool (e.g., automated dispensing tool). The dispensing tool may dispense the adhesive layer 660 in a frame shape around the package module 120. At the time of application, the adhesive layer 660 may be sufficiently rigid so as to form a semi-solid bead on the surface of the package substrate 110. In at least one embodiment, a viscosity of each the adhesive layer 660 at the time of application may be 50,000 centipoise (cp) or greater. Due in part to the viscosity of the adhesive layer 660, the shape of the semi-solid bead may remain substantially unchanged between the time of application by the dispensing tool and the later time of attaching the stiffener ring 650. The location of the frame shape of the adhesive layer 660 may correspond to a location of the stiffener ring 650 (e.g., see FIG. 4B). A pressing of the stiffener ring 650 onto the adhesive layer 660 may deform the adhesive layer 660.

FIG. 5E illustrates a vertical cross-sectional view of an intermediate structure in which the stiffener ring 650 may be attached to (e.g., mounted on) the package substrate 110 according to one or more embodiments. In at least one embodiment, the package substrate 110 with the package module 120 may be placed on a surface. The stiffener ring 650 may then be positioned over the package substrate 110, for example, by an electromechanical pick-and-place (PNP) machine. The stiffener ring 650 may then be lowered down around the package module 120 and onto the package substrate 110. The stiffener ring 650 may then be aligned with the adhesive layer 660 formed on the package substrate 110. The stiffener ring 650 may then be pressed downward onto the package substrate 100 so that the stiffener ring 650 may be attached to the package substrate 110 through the adhesive layer 660.

The stiffener ring 650 may be clamped to the package substrate 110 for a period to allow the adhesive layer 660 to cure and form a secure bond between the package substrate 110 and the stiffener ring 650. The clamping of the stiffener ring 650 to the package substrate 110 may be performed, for example, by using a heat clamp module. The heat clamp module may apply a uniform force across the upper surface of the stiffener ring 650. In one or more embodiments, the heat clamp module may apply the pressing force to the stiffener ring 650 and provide an increase in temperature to promote the curing of the adhesive layer 660.

FIG. 5F illustrates a vertical cross-sectional view of an intermediate structure in which a plurality of solder balls 110c may be formed on the package substrate 110 according to one or more embodiments. The plurality of solder balls 110c may be formed on an exposed surface of the package substrate lower bonding pads 116a (e.g., through openings (not shown) in the package substrate lower passivation layer 110b). The solder balls 110c may be formed, for example, by an electroplating process. The solder balls 110c may be formed, for example, so as to be located under the stiffener ring 650 and under the package module 120 and therebetween. The plurality of solder balls 110c may constitute a ball-grid array (BGA) that may allow the package structure 100 to be securely mounted (e.g., by surface mount technology (SMT)) on a substrate such as a printed circuit board and electrically coupled to the substrate. Formation of the solder balls 110c may complete the formation of the package structure 100.

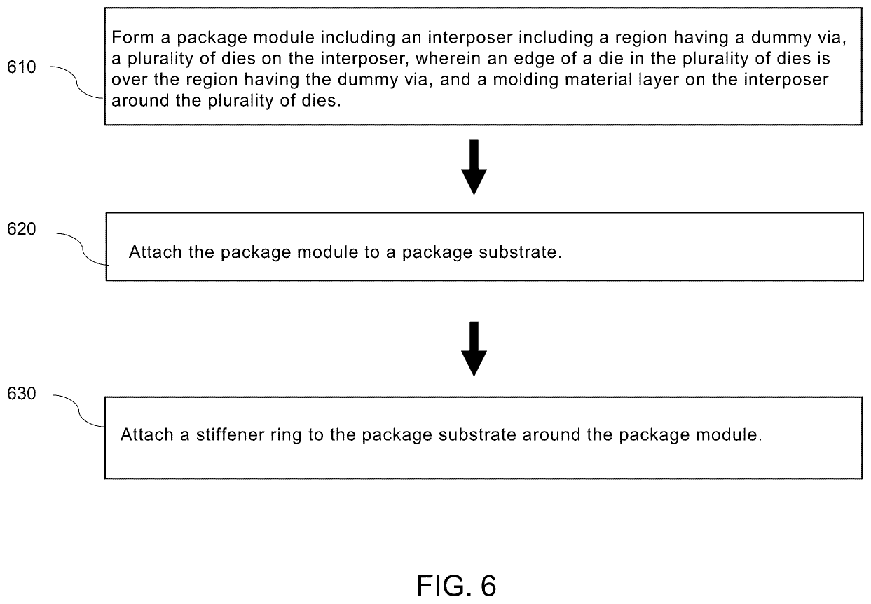

FIG. 6 is a flow chart illustrating a method of forming a package module according to one or more embodiments. Step 610 includes forming a package module including an interposer including a region having a dummy via, a plurality of dies on the interposer, wherein an edge of a die in the plurality of dies is over the region having the dummy via, and a molding material layer on the interposer around the plurality of dies. Step 620 includes attaching the package module to a package substrate. Step 630 includes attaching a stiffener ring to the package substrate around the package module.

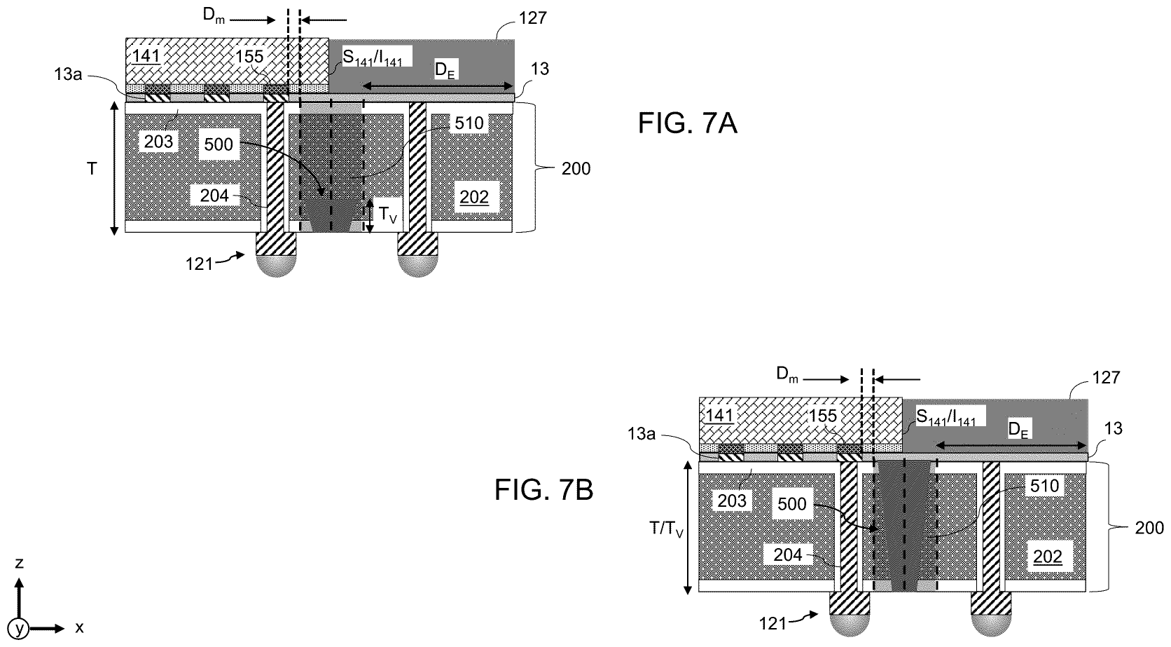

FIG. 7A-7B are detailed vertical cross-sectional views of alternative designs of the interposer 200 according to one or more embodiments. FIG. 7A is a detailed vertical cross-sectional view of a first alternative design of the position of the dummy vias 500 formed within the interposer 200 according to one or more embodiments. As illustrated in FIG. 7A, in the first alternative design, the dummy via 500 may be located in a lowermost portion of the semiconductor material layer 202. The thickness T_{V} of the dummy via 500 may be less than the total thickness T of the interposer 200. As shown in FIG. 7A, the dummy via 500 may be formed within the dummy via formation region 510, but in a lower portion of the dummy via formation region 510 compared to the embodiments shown in FIGS. 1A-2E and 4A-5F. The thickness T_{V} and vertical and horizontal cross sectional area shapes of the dummy via 500 may be the same as the embodiments shown in FIGS. 1A-2E and 4A-5F.

FIG. 7B is a detailed vertical cross-sectional view of a second alternative design of the interposer 200 according to one or more embodiments. As illustrated in FIG. 7B, in the second alternative design, the dummy via 500 may extend through an entire thickness of semiconductor material layer 202 and through an entire thickness of the interposer 200 in the z-direction. A center of the dummy via 500 in the z-direction may be substantially aligned with a center of the semiconductor material layer 202 in the z-direction. The thickness T_{V} of the dummy via 500 may be substantially the same as the total thickness T of the interposer 200 (e.g., T_{V}=T; see FIG. 1D). As shown in FIG. 7B, the dummy via 500 may remain within the dummy via formation region 510, but may have as substantially greater thickness T_{V} than in the embodiments of FIGS. 1A-2E, 4A-5F, and 7A. The vertical and horizontal cross sectional area shapes may be the same as the embodiments shown in FIGS. 1A-2E and 4A-5F, and 7A. While the embodiment illustrated in FIG. 7B shows the dummy via 500 extending through the entire thickness of the interposer 200, the dummy via 500 in the second alternative design may be formed in less than the entire thickness of the interposer 200.

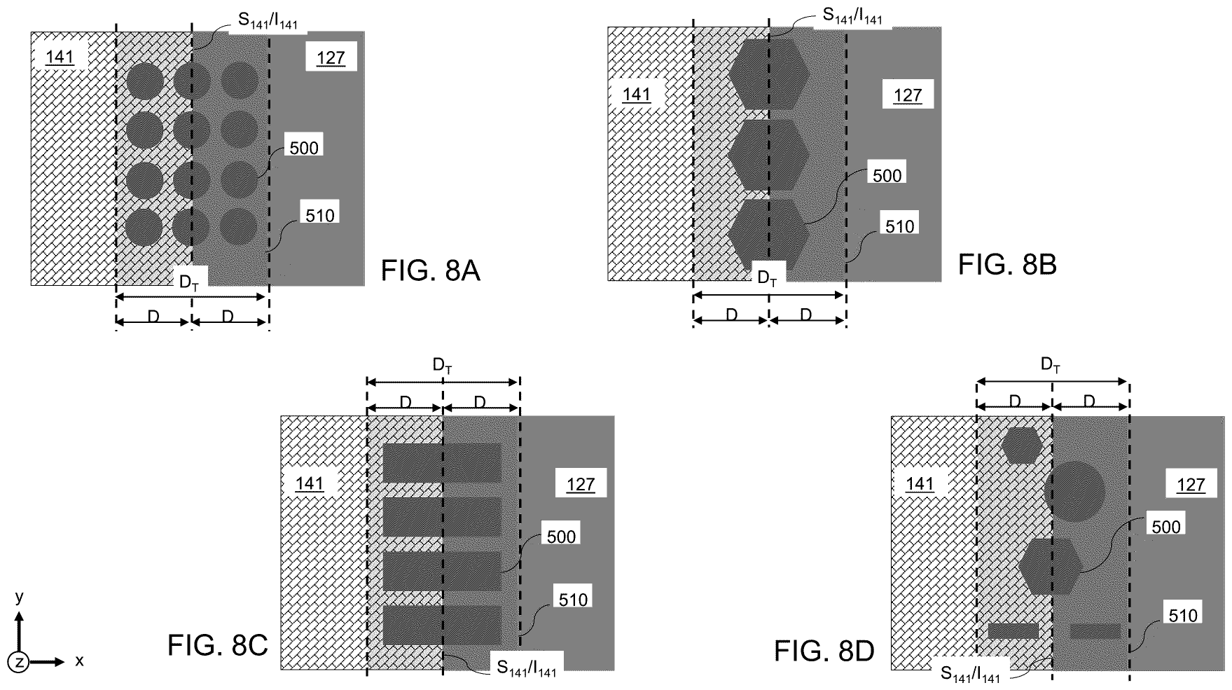

FIG. 8A-8C are detailed plan views of alternative design patterns of the dummy vias 500 according to one or more embodiments. FIG. 8A is a detailed vertical cross-sectional view of a first alternative design pattern of the dummy vias 500 according to one or more embodiments. As illustrated in FIG. 8A, in the first alternative design pattern, the dummy vias 500 may be arranged in an array having a plurality of rows (in the x-direction) and columns (in the y-direction). The dummy vias 500 in the array may be formed continuously around the entire periphery of the first semiconductor die 141 so as to form a frame-shaped array. It should be noted that although FIG. 8A illustrates three columns of dummy vias 500, more or fewer columns of dummy vias 500 are contemplated by the present disclosure.

FIG. 8B is a detailed vertical cross-sectional view of a second alternative design pattern of the dummy vias 500 according to one or more embodiments. As illustrated in FIG. 8B, in the second alternative design pattern, the dummy vias 500 may have a polygon shape in a plan view. Although the polygon shape in FIG. 8B is a hexagon, the polygon shape is not limited to a hexagon but may include a pentagon, octagon, etc. Further, the polygon shape may be regular or irregular. The dummy vias 500 may also be formed continuously around the entire periphery of the first semiconductor die 141 so as to form a frame-shape. It should be noted that although FIG. 8B illustrates one column of dummy vias 500, more columns of dummy vias 500 (e.g., having a smaller width in the x-direction) are contemplated by the present disclosure.

FIG. 8C is a detailed vertical cross-sectional view of a third alternative design pattern of the dummy vias 500 according to one or more embodiments. As illustrated in FIG. 8C, in the third alternative design pattern, the dummy vias 500 may have a rectangular shape. In particular, a longitudinal direction of the dummy vias 500 may extend in a direction perpendicular to the sidewall S₁₄₁ of the first semiconductor die 141. In at least one embodiment, a longitudinal direction of the dummy vias 500 may extend in a direction perpendicular to an interface between the sidewall S₁₄₁ of the first semiconductor die 141 and the molding material layer 127. The dummy vias 500 may also be formed continuously around the entire periphery of the first semiconductor die 141 so as to form a frame-shape. It should be noted that although FIG. 8C illustrates one column of dummy vias 500, more columns of dummy vias 500 (e.g., having a smaller length in the x-direction) are contemplated by the present disclosure.

FIG. 8D is a detailed vertical cross-sectional view of a fourth alternative design pattern of the dummy vias 500 according to one or more embodiments. As illustrated in FIG. 8D, in the fourth alternative design pattern, the dummy vias 500 located in the dummy via formation region 510 may have a variety of shapes. These horizontal cross sectional shapes may include hexagons, circles, rectangles. In addition, the dummy vias 500 may be arranged in offset columns. In the embodiment of FIG. 8D, the dummy vias 500 may be located within the dummy via formation region 510, but offset some distances from the center of dummy via formation region 510. The dummy vias 500 may also be formed continuously around the entire periphery of the first semiconductor die 141 so as to form a frame-shape.

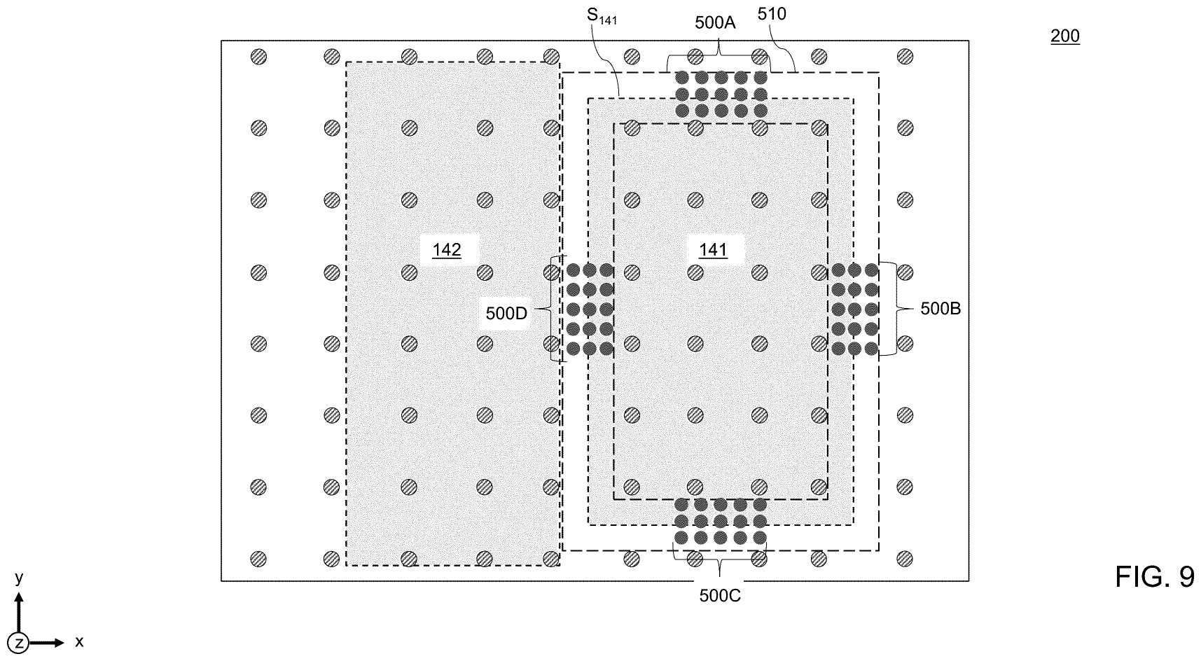

FIG. 9 is a plan view (e.g., top-down view) of the interposer 200 having a fourth alternative design pattern of the dummy vias 500 according to one or more embodiments. As illustrated in FIG. 9, in the fourth alternative design pattern, the pattern of dummy vias 500 may include a plurality of separate dummy via groups 500A-500D. The dummy via groups 500A-500D (like the individual dummy vias 500) may be located in a part of the dummy via formation region 510 determined to be in need of structural support. The dummy via groups 500 may have a regular or irregular arrangement. While the dummy via groups 500A-500D in FIG. 9 have the same number of dummy vias 500 with a substantially same arrangement and having substantially the same shape and size, it is possible for the dummy via groups 500A-500D to have different numbers of dummy vias 500 with different arrangements and different cross-sectional shapes and sizes.

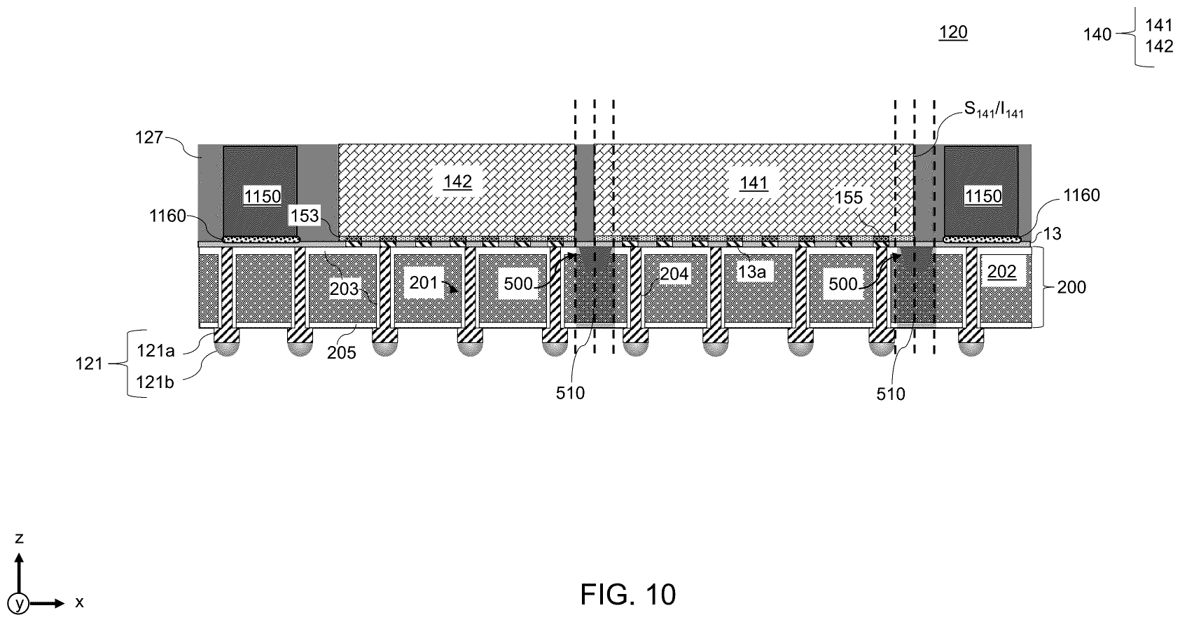

FIG. 10 is a vertical cross-sectional view of an alternative design of the package module 120 according to one or more embodiments. In the alternative design of FIG. 10, the package module 120 may include a module stiffener 1150 (e.g., embedded module stiffener). The module stiffener 1150 may be located in the molding material layer 127 adjacent to the semiconductor dies 140. In at least one embodiment, the module stiffener 1150 may have a ring shape (e.g., frame shape) and laterally (in the x-direction and y-direction) surround the semiconductor dies 140. The module stiffener 1150 may be attached to the interposer 200 by an adhesive 1160 (e.g., a silicone adhesive or an epoxy adhesive) and may be substantially similar to the adhesive 660 (e.g., see FIG. 4A). The module stiffener 1150 may be formed of substantially the same materials as the stiffener ring 650 (e.g., see FIGS. 4A and 4B). In particular, a material of the module stiffener 1150 may include any kind of metal, alloy, polymer, semiconductor or a combination (e.g., composite) of any of these materials.

A shape (e.g., structure) of the module stiffener 1150 may be any shape. A thickness (e.g., in the z-direction) of the module stiffener 1150 may be in a range from about 0.1 mm to about 5.0 mm. In at least one embodiment, a minimum thickness of the module stiffener 1150 may be about 0.5 mm. In at least one embodiment, the thickness of the module stiffener 1150 may be less than a thickness of the semiconductor dies 140 in the package module 120. The module stiffener 1150 may or may not be exposed at the upper surface of a molding material layer 127 in which the module stiffener 1150 is embedded. The module stiffener 1150 may have no active or passive device function.

The module stiffener 1150 may help to control overall warpage in the package module 120. In particular, the module stiffener may mitigate warpage of the package module 120 at low and high temperatures. In at least one embodiment, a material of the module stiffener 1150 may be selected to provide a proper coefficient of thermal expansion (CTE)) for the module stiffener 1150 for mitigating warpage of the package module 120. By helping to mitigate warpage of the package module 120 (e.g., mitigating a curve (e.g., crying shape) of the package module 120), the module stiffener 1150 may help to reduce a bending of the interposer 200 during a probing test, and thereby reduce a risk of cracks in the interposer 200 caused by the probing test.

Referring now to FIGS. 1A-10, a package module 120 may include an interposer 200 including a dummy via formation region 510 having at least one dummy via 500, a plurality of semiconductor dies 140 on the interposer 200, wherein an edge of a semiconductor die 141 in the plurality of semiconductor dies 140 may be over the dummy via formation region 510, and a molding material layer 127 on the interposer 200 encapsulating the plurality of semiconductor dies 140.

In one embodiment, the molding material layer 127 contacts the edge of the semiconductor die 141 at an interface I₁₄₁, and the interface I₁₄₁ may be located over the dummy via formation region 510. In one embodiment, the edge of the semiconductor die 141 may be located over a center of the dummy via formation region 510. In one embodiment, the edge of the semiconductor die 141 may be located over a center of the dummy via 500. In one embodiment, the dummy via formation region 510 may be located under a periphery of the semiconductor die 141. In one embodiment, the interposer 200 may include a semiconductor material layer 202 and the at least one dummy via 500 may be located in one of an uppermost portion of the semiconductor material layer 202, or a lowermost portion of the semiconductor material layer 202. In one embodiment, a thickness TV of the at least one dummy via 500 may be equal to a total thickness T of the interposer 200. In one embodiment, the dummy via 500 may include a plurality of dummy vias 500 having a dummy via pattern. In one embodiment, the plurality of dummy vias 500 may include a plurality of rows of dummy vias 500 substantially aligned in a direction perpendicular to the edge of the semiconductor die 141. In one embodiment, the plurality of dummy vias 500 may include a column of dummy vias 500 substantially aligned with the edge of the semiconductor die 141. In one embodiment, the plurality of semiconductor dies 140 may be connected to the interposer 200 by a hybrid bond. In one embodiment, a thickness T_{V} of the at least one dummy via 500 may be greater than 1 μm and less than or equal to a total thickness T of the interposer 200. An overlap distance between the edge of the semiconductor die 141 and an edge of the dummy via formation region 510 may be less than or equal to 2 mm. In one embodiment, the dummy via 500 may include a plurality of dummy vias 500 and an area ratio of a total area of the plurality of dummy dies and an area of the dummy via formation region 510 may be in range from 0.1 to 0.99.

Referring again to FIGS. 1A-10, a method of making a package module 120 may include forming an interposer 200 including a dummy via formation region 510 having at least one dummy via 500, attaching a plurality of semiconductor dies 140 to the interposer 200, wherein an edge of a semiconductor die 141 in the plurality of semiconductor dies 140 may be over the dummy via formation region 510, and forming a molding material layer 127 on the interposer to encapsulate the plurality of semiconductor dies 140. In one embodiment, the forming of the molding material layer 127 may include forming the molding material layer 127 to contact the edge of the semiconductor die 141 at an interface I₁₄₁, such that the interface I₁₄₁ may be located over the dummy via formation region 510. In one embodiment, the attaching of the plurality of semiconductor dies 140 may include attaching the plurality of semiconductor dies 140 such that an edge of the semiconductor die 141 may be located over a center of the dummy via formation region 510.

Referring again to FIGS. 1A-10, a package structure 100 may include a package substrate 110, a package module 120 on the package substrate 110 including an interposer 200 including a dummy via formation region 510 having a dummy via, a plurality of semiconductor dies 140 on the interposer 200, wherein an edge of a semiconductor die 141 in the plurality of semiconductor dies 140 may be over the dummy via formation region 510, and a molding material layer 127 on the interposer 200 encapsulating the plurality of semiconductor dies 140, and a stiffener ring 650 on the package substrate 110 around the package module 120. A distance DE between the dummy via formation region 510 and an outer sidewall of the interposer 200 may be greater than an inner distance Di between the outer sidewall of the interposer 200 and an inner edge 650a of the stiffener ring 650.

The various embodiment interposers 10 disclosed herein may include dummy vias 500 formed in a dummy via formation region 510. The dummy vias 500 may be formed in a variety of cross-sectional shapes and sizes. The dummy vias 500 may enhance a structure of the package module that the dummy vias 500 are formed as a part of and mitigate against the risk of an interposer crack. The various embodiments disclosed herein may reduce interposer crack more than 95% during probing tests.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package module, comprising:
an interposer including a dummy via formation region having at least one dummy via;
a plurality of semiconductor dies on the interposer, wherein an edge of a semiconductor die in the plurality of semiconductor dies is over the dummy via formation region; and
a molding material layer on the interposer encapsulating the plurality of semiconductor dies.

2. The package module of claim 1, wherein the molding material layer contacts the edge of the semiconductor die at an interface, and the interface is located over the dummy via formation region.

3. The package module of claim 1, wherein the edge of the semiconductor die is located over a center of the dummy via formation region.

4. The package module of claim 1, wherein the edge of the semiconductor die is located over a center of the at least one dummy via.

5. The package module of claim 1, wherein the dummy via formation region is located under a periphery of the semiconductor die.

6. The package module of claim 1, wherein the molding material layer is located over the dummy via formation region.

7. The package module of claim 1, wherein the interposer comprises a semiconductor material layer and the at least one dummy via is located in one of:
an uppermost portion of the semiconductor material layer; or
a lowermost portion of the semiconductor material layer.

8. The package module of claim 1, wherein a thickness of the at least one dummy via is substantially equal to a total thickness of the interposer.

9. The package module of claim 1, wherein the at least one dummy via comprises a plurality of dummy vias having a dummy via pattern.

10. The package module of claim 9, wherein the plurality of dummy vias comprises a plurality of rows of dummy vias substantially aligned in a direction perpendicular to the edge of the semiconductor die.

11. The package module of claim 9, wherein the plurality of dummy vias comprises a column of dummy vias substantially aligned with the edge of the semiconductor die.

12. The package module of claim 1, wherein the plurality of semiconductor dies is connected to the interposer by hybrid bonding.

13. The package module of claim 1, wherein a thickness of the at least one dummy via is greater than 1 μm and less than or equal to a thickness of the interposer.

14. The package module of claim 1, wherein an overlap distance between the edge of the semiconductor die and an edge of the dummy via formation region is less than or equal to 2 mm.

15. The package module of claim 1, wherein the at least one dummy via comprises a plurality of dummy vias and an area ratio of a total area of a plurality of dummy dies to an area of the dummy via formation region is in range from 0.1 to 0.99.

16. A method of making a package module, the method comprising:
forming an interposer including a dummy via formation region having at least one dummy via;
attaching a plurality of semiconductor dies to the interposer, wherein an edge of a semiconductor die in the plurality of semiconductor dies is over the dummy via formation region; and
forming a molding material layer on the interposer to encapsulate the plurality of semiconductor dies.

17. The method of claim 16, wherein the forming of the molding material layer comprises forming the molding material layer to contact the edge of the semiconductor die at an interface, such that the interface is located over the dummy via formation region.

18. The method of claim 16, wherein the attaching of the plurality of semiconductor dies comprises attaching the plurality of semiconductor dies such that an edge of the semiconductor die is located over a center of the dummy via formation region.

19. A package structure, comprising:
a package substrate;
a package module on the package substrate, comprising:
an interposer including a dummy via formation region having at least one dummy via;
a plurality of semiconductor dies on the interposer, wherein an edge of a semiconductor die in the plurality of semiconductor dies is over the dummy via formation region; and
a molding material layer on the interposer encapsulating the plurality of semiconductor dies; and
a stiffener ring on the package substrate around the package module.

20. The package structure of claim 19, wherein a distance between the dummy via formation region and an outer sidewall of the interposer, is greater than a distance between the outer sidewall of the interposer and an inner edge of the stiffener ring.
